(19) United States
(12) Patent Application Publication
(10) Pub. No.: US 2025/0279264 A1
(43) Pub. Date: Sep. 4, 2025

(54) SUBSTRATE PROCESSING SYSTEM AND TRANSFER METHOD

(71) Applicant: Tokyo Electron Limited, Tokyo (JP)

(72) Inventors: Toshiki AKAMA, Miyagi (JP); Shusei KATO, Miyagi (JP); Gyeong min PARK, Miyagi (JP); Nobutaka SASAKI, Miyagi (JP)

(73) Assignee: Tokyo Electron Limited, Tokyo (JP)

(21) Appl. No.: 19/192,545

(22) Filed: Apr. 29, 2025

Related U.S. Application Data
(63) Continuation of application No. PCT/JP2023/038477, filed on Oct. 25, 2023.

(30) Foreign Application Priority Data
Oct. 31, 2022 (JP) 2022-174836

(51) Int. Cl. H01J 37/32

(52) U.S. Cl. CPC H01J 37/32807; H01J 37/32642; H01J 37/32853; H01J 37/3288

(57) ABSTRACT

A substrate processing system includes: a processing module including a processing chamber, a substrate support configured to support a substrate and a ring disposed at a periphery of the substrate in the processing chamber, and a lifter configured to raise and lower the ring; a vacuum transfer module connected to the processing module and including a transfer robot configured to transfer the ring; and a controller. The controller performs: (A) raising the lifter to allow the ring to be spaced apart from a support surface of the substrate support; (B) after step (A), acquiring an index related to a position misalignment amount of the ring; and (C) determining whether to correct a position of the ring based on the index related to the position misalignment amount, which is acquired in step (B).

### CROSS-REFERENCE TO RELATED APPLICATIONS

The application is a Bypass Continuation application of PCT International Application No. PCT/JP2023/038477, filed on Oct. 25, 2023 and designating the United States, the international application being based upon and claiming the benefit of priority from Japanese Patent Application No. 2022-174836, filed on Oct. 31, 2022, the entire content of each are incorporated herein by reference.

### TECHNICAL FIELD

The present disclosure relates to a substrate processing system and a transfer method.

### BACKGROUND

Patent Document 1 discloses a plasma processing apparatus which performs a plasma processing on a substrate placed on a stage (substrate support) provided inside a processing chamber by disposing a focus ring (ring) at a periphery of the substrate support. A substrate processing system including the plasma processing apparatus performs an operation of, when exchanging the ring, taking out the ring from the substrate support by a transfer robot, cleaning a surface on which the ring is placed, and placing a ring on the substrate support again.

### PRIOR ART DOCUMENTS

### Patent Documents

Patent Document 1: Japanese Patent Laid-Open Publication No. 2018-010992

### SUMMARY

According to one embodiment of the present disclosure, there is provided a substrate processing system including: a processing module including a processing chamber, a substrate support configured to support a substrate and a ring disposed at a periphery of the substrate in the processing chamber, and a lifter configured to raise and lower the ring; a vacuum transfer module connected to the processing module and including a transfer robot configured to transfer the ring; and a controller. The controller performs: (A) raising the lifter to allow the ring to be spaced apart from a support surface of the substrate support; (B) after step (A), acquiring an index related to a position misalignment amount of the ring; and (C) determining whether to correct a position of the ring based on the index related to the position misalignment amount, which is acquired in step (B).

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating an example of a substrate processing system according to an embodiment.

FIG. 2 is a schematic cross-sectional view illustrating an example of a plasma processing apparatus.

FIG. 3 is an enlarged view of a portion in FIG. 2.

FIG. 4 is a view illustrating a cause of a position misalignment which occurs in a ring when taking out the ring from a substrate support.

FIG. 5A is a view illustrating a first example of detecting an index related to a position misalignment amount of an inner ring. FIG. 5B is a view illustrating a second example of detecting an index related to a position misalignment amount of the inner ring. FIG. 5C is a view illustrating a third example of detecting an index related to a position misalignment amount of the inner ring.

FIG. 6 is a flowchart illustrating an operation sequence when taking out an edge ring.

FIG. 7 is a flowchart illustrating a processing flow of a misalignment identification and correction processing in a transfer method according to a first example.

FIG. 8A is a first view illustrating an operation of the misalignment identification and correction processing. FIG. 8B is a second view illustrating an operation continued from FIG. 8A. FIG. 8C is a third view illustrating an operation continued from FIG. 8B. FIG. 8D is a fourth view illustrating an operation continued from FIG. 8C. FIG. 8E is a fifth view illustrating an operation continued from FIG. 8D. FIG. 8F is a sixth view illustrating an operation continued from FIG. 8E.

FIG. 9 is a flowchart illustrating a modification of the processing flow of the misalignment identification and correction processing according to the first example.

FIG. 10 is a flowchart illustrating a processing flow in a transfer method according to a second example.

FIG. 11 is a schematic cross-sectional view illustrating another example of the plasma processing apparatus.

FIG. 12 is a flowchart illustrating a processing flow in a transfer method according to a third example.

FIG. 13A is a first view illustrating a misalignment resolution operation. FIG. 13B is a second view illustrating an operation continued from FIG. 13A. FIG. 13C is a third view illustrating an operation continued from FIG. 13B.

FIG. 14 is a flowchart illustrating a processing flow in a transfer method according to a fourth example.

FIG. 15 is a flowchart illustrating a processing flow in a transfer method according to a fifth example.

FIG. 16 is a flowchart illustrating a processing flow in a transfer method according to a sixth example.

FIG. 17 is a view illustrating an example of imaging an inclined edge ring by a camera.

FIG. 18 is a view illustrating a modification of a configuration which performs a leakage check of gas as an index related to a position misalignment amount of the edge ring.

FIG. 19 is a flowchart illustrating a transfer operation sequence of the edge ring according to a modification.

FIG. 20A is a view illustrating a relationship between a position of the edge ring and positions of position detection sensors. FIG. 20B is a view illustrating a change in sensor output of the position detection sensors when transferring the edge ring from one position to the other position.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments for implementing the present disclosure will be described with reference to the drawings. In the respective drawings, the same components may be denoted by the same reference numerals, and duplicated descriptions thereof may be omitted.

### [Substrate Processing System]

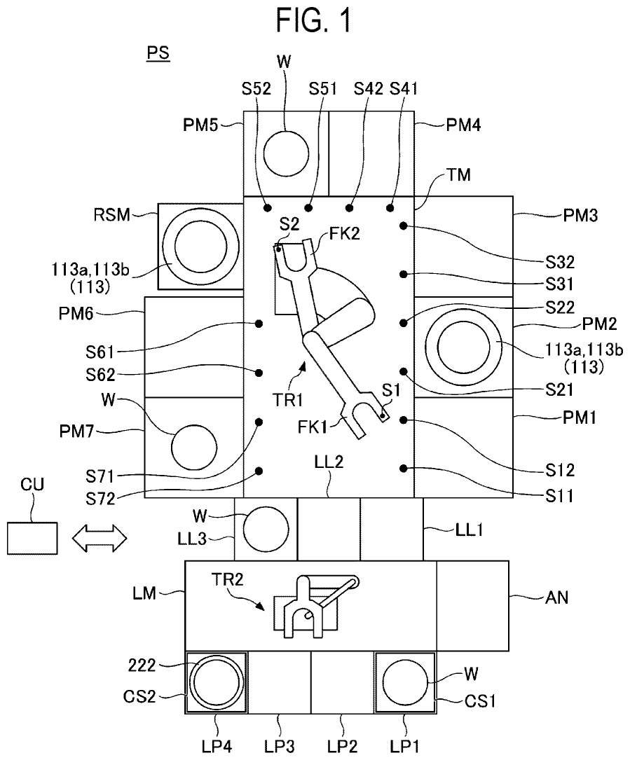

A substrate processing system PS according to an embodiment is described with reference to FIG. 1. FIG. 1 is a view illustrating an example of the substrate processing system PS according to the embodiment. As illustrated in FIG. 1, the substrate processing system PS is a system capable of performing various types of processings, such as a plasma processing, on a substrate W. The substrate W may be, for example, a semiconductor wafer.

The substrate processing system PS includes a vacuum transfer module TM, a plurality of processing modules PM1 to PM7, a ring accommodation module RSM, a plurality of load lock modules LL1 to LL3, an atmospheric transfer module LM, load ports LP1 to LP4, an aligner AN, and a controller CU. The vacuum transfer module TM is also referred to as a transfer module. The processing modules PM1 to PM7 are also referred to as process modules. The ring accommodation module RSM is also referred to as a ring stocker module. The atmospheric transfer module LM is also referred to as a loader module.

The vacuum transfer module TM has a quadrangular shape in a plan view. The processing modules PM1 to PM7, the load lock modules LL1 to LL3, and the ring accommodation module RSM are connected to the vacuum transfer module TM. The vacuum transfer module TM includes a vacuum transfer chamber. The vacuum transfer chamber is maintained in a vacuum atmosphere. A transfer robot TR1 is installed in the vacuum transfer chamber (inside the vacuum transfer module TM).

The transfer robot TR1 is configured to be rotatable, extensible, and movable vertically. The transfer robot TR1 includes an upper fork FK1 and a lower fork FK2. The upper fork FK1 and the lower fork FK2 of the transfer robot TR1 are configured to be capable of holding each of the substrate W and a ring 113 (an inner ring 113a and an outer ring 113b). The transfer robot TR1 holds and transfers the substrate W and the ring 113 among the processing modules PM1 to PM7, the load lock modules LL1 to LL3, and the ring accommodation module RSM.

The upper fork FK1 is provided with a position detection sensor S1. The lower fork FK2 is provided with a position detection sensor S2. The position detection sensors S1 and S2 detect positions of the inner ring 113a and the outer ring 113b, which are loaded in the processing modules PM1 to PM7. The position detection sensors S1 and S2 may be, for example, optical displacement sensors, cameras or the like.

The vacuum transfer module TM may be provided with position detection sensors S11 and S12. The position detection sensors S11 and S12 are installed on a transfer path of the substrate W and the ring 113 (the inner ring 113a), which are transferred from the vacuum transfer module TM to the processing module PM1. The position detection sensors S11 and S12 are used when loading the substrate W or the ring 113 from the vacuum transfer module TM to the processing module PM1 and when unloading the substrate W or the ring 113 from the processing module PM1 to the vacuum transfer module TM. The position detection sensors S11 and S12 are installed, for example, in a vicinity of a gate valve (not illustrated) which partitions the vacuum transfer module TM and the processing module PM1. The position detection sensors S11 and S12 are disposed, for example, such that a distance between the position detection sensors S11 and S12 is smaller than an outer diameter of the substrate W and is smaller than an inner diameter of the inner ring 113a. Like the position detection sensors S11 and S12, the vacuum transfer module TM may be provided with position detection sensors S21, S22, S31, S32, S41, S42, S51, S52, S61, S62, S71, and S72.

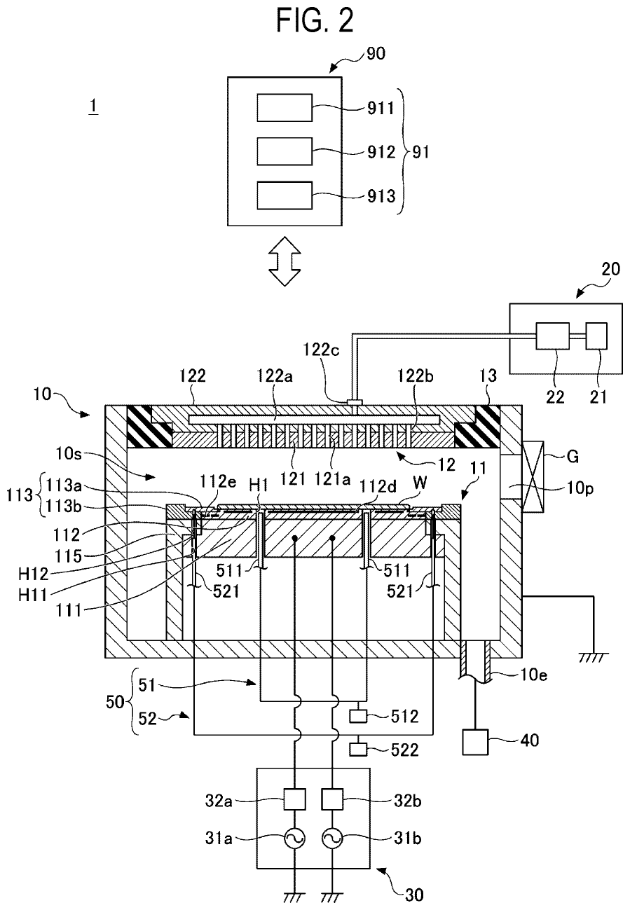

The processing modules PM1 to PM7 are connected to the vacuum transfer module TM. The processing modules PM1 to PM7 have vacuum processing chambers. A substrate support 11 (see FIG. 2) is installed inside the vacuum processing chamber. After the substrate W is placed on the substrate support 11, the processing modules PM1 to PM7 reduce the internal pressure, introduce a processing gas, and apply RF power applied to generate plasma, whereby a plasma processing is performed on the substrate W by the plasma. The vacuum transfer module TM is partitioned from the processing modules PM1 to PM7 by openable/closable gate valves (not illustrated).

The ring accommodation module RSM is an example of an apparatus which accommodates the ring 113, and is connected to the vacuum transfer module TM. The ring accommodation module RSM accommodates, for example, the inner ring 113a and the outer ring 113b, which constitute the ring 113. The ring accommodation module RSM may be configured to accommodate only the inner ring 113a. The ring accommodation module RSM may be configured to accommodate only the outer ring 113b. The inner ring 113a and the outer ring 113b are transferred between the processing modules PM1 to PM7 and the ring accommodation module RSM by the transfer robot TR1. The vacuum transfer module TM and the ring accommodation module RSM are partitioned by an openable/closable gate valve (not illustrated).

The load lock modules LL1 to LL3 are installed between the vacuum transfer module TM and the atmospheric transfer module LM. The load lock modules LL1 to LL3 are connected to the vacuum transfer module TM and the atmospheric transfer module LM. Each of the load lock modules LL1 to LL3 includes therein an internal pressure variable chamber of which an inside is switchable between vacuum and atmospheric pressure. The internal pressure variable chamber is provided with a stage (not illustrated) which enables the substrate W to be placed thereon. When transferring the substrate W from the atmospheric transfer module LM to the vacuum transfer module TM, the load lock modules LL1 to LL3 receive the substrate W from the atmospheric transfer module LM while maintaining the inside of the internal pressure variable chamber at the atmospheric pressure, and then depressurize the inside of the internal pressure variable chamber to transfer the substrate W to the vacuum transfer module TM. When transferring the substrate W from the vacuum transfer module TM to the atmospheric transfer module LM, the load lock modules LL1 to LL3 receive the substrate W from the vacuum transfer module TM while maintaining the inside of the internal pressure variable chamber in the vacuum, and then pressurize the inside of the internal pressure variable chamber to the atmospheric pressure to transfer the substrate W to the atmospheric transfer module LM. The load lock modules LL1 to LL3 are partitioned from the vacuum transfer module TM by openable/closable gate valves (not illustrated). The load lock modules LL1 to LL3 are partitioned from the atmospheric transfer module LM by openable/closable gate valves (not illustrated).

The atmospheric transfer module LM is installed to face the vacuum transfer module TM. The atmospheric transfer module LM may be, for example, an equipment front end module (EFEM). The atmospheric transfer module LM has a quadrangular shape in a plan view. The atmospheric transfer module LM includes an atmospheric transfer chamber. An inside of the atmospheric transfer chamber is maintained in an atmospheric pressure atmosphere. A transfer robot TR2 is installed inside the atmospheric transfer chamber. The transfer robot TR2 holds and transfers the substrate W among the load ports LP1 to LP4, the aligner AN, and the load lock modules LL1 to LL3. The atmospheric transfer module LM may have a fan filter unit (FFU).

The load ports LP1 to LP4 are connected to the atmospheric transfer module LM. A plurality of substrate accommodation containers CS1 is placed in the load lock ports LP1 to LP4. The substrate accommodation container CS1 may be, for example, a front-opening unified pod (FOUP) which accommodates a plurality of substrates W (for example, 25 substrates W).

The aligner AN is connected to the atmospheric transfer module LM. The aligner AN is configured to perform position adjustment of the substrate W. The aligner AN may be installed inside the atmospheric transfer chamber.

The controller CU controls each part of the substrate processing system PS. The controller CU controls, for example, an operation of the transfer robot TR1 installed in the vacuum transfer module TM, an operation of the transfer robot TR2 installed in the atmospheric transfer module LM, and opening and closing of the gate valves. The controller CU may be, for example, a computer. The controller CU includes a central processing unit (CPU) which is a processor, a random access memory (RAM), a read only memory (ROM), an auxiliary storage device, and the like. The CPU operates based on a program stored in the ROM or the auxiliary storage device, and controls each part of the substrate processing system PS.

### [Plasma Processing Apparatus]

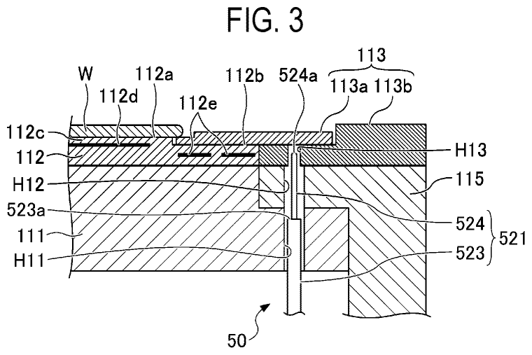

An example of a plasma processing apparatus 1 applied to the processing modules PM1 to PM7 in FIG. 1 is described with reference to FIGS. 2 and 3. FIG. 2 is a schematic cross-sectional view illustrating an example of the plasma processing apparatus 1. FIG. 3 is an enlarged view of a portion in FIG. 2.

The plasma processing apparatus 1 includes a plasma processing chamber 10 (processing chamber), a gas supply 20, an RF power supply 30, an exhaust system 40, a lifter 50, and a controller 90.

The plasma processing chamber 10 includes a substrate support 11 and an upper electrode 12. The substrate support 11 is disposed in a lower region of a plasma processing space 10s in the plasma processing chamber 10. The upper electrode 12 is disposed above the substrate support 11, to function as a portion of a ceiling plate of the plasma processing chamber 10.

The substrate support 11 supports the substrate W in the plasma processing space 10s. The substrate support 11 includes a lower electrode 111, an electrostatic chuck 112, a ring 113 (hereinafter, also referred to as a ring assembly 113), and an insulating member 115.

The electrostatic chuck 112 is disposed on the lower electrode 111. The electrostatic chuck 112 has an upper surface which includes a substrate support surface 112a and a ring support surface 112b. The electrostatic chuck 112 supports the substrate W on the substrate support surface 112a. The electrostatic chuck 112 supports the inner ring 113a on the ring support surface 112b. The electrostatic chuck 112 includes an insulating member 112c, a first attraction electrode 112d, and a second attraction electrode 112e. The first attraction electrode 112d and the second attraction electrode 112e are embedded in the insulating member 112c. The first attraction electrode 112d is located below the substrate support surface 112a. The electrostatic chuck 112 attracts and holds the substrate W on the substrate support surface 112a by applying a voltage to the first attraction electrode 112d. The second attraction electrode 112e is located below the ring support surface 112b. The electrostatic chuck 112 attracts and holds the inner ring 113a on the ring support surface 112b by applying a voltage to the second attraction electrode 112e. In the examples in FIGS. 2 and 3, the electrostatic chuck 112 includes a monopolar electrostatic chuck that attracts and holds the substrate W, and a bipolar electrostatic chuck that attracts and holds the inner ring 113a. A bipolar electrostatic chuck may be used instead of the monopolar electrostatic chuck, and a monopolar electrostatic chuck may be used instead of the bipolar electrostatic chuck.

The ring assembly 113 includes the inner ring 113a and the outer ring 113b. The inner ring 113a has an annular shape. The inner ring 113a is placed on the ring support surface 112b to surround the substrate W. The inner ring 113a improves uniformity of a plasma processing on the substrate W. The inner ring 113a is made of, for example, a conductive material such as silicon (Si) or silicon carbide (SiC). Further, the inner ring 113a may be made of an insulating material such as quartz. The outer ring 113b has an annular shape. The outer ring 113b is disposed on an outer peripheral portion of the inner ring 113a. The outer ring 113b protects an upper surface of the insulating member 115 from, for example, plasma. The outer ring 113b is made of, for example, an insulating material such as quartz. Further, the outer ring 113b may be made of a conductive material such as silicon or silicon carbide. In the illustrated example, an inner peripheral portion of the outer ring 113b is located inward of the outer peripheral portion of the inner ring 113a, the outer peripheral portion of the inner ring 113a is located outward of the inner peripheral portion of the outer ring 113b, and the inner ring 113a and the outer ring 113b partially overlap each other in top view. Accordingly, when a plurality of supporting pins 521 to be described later is raised and lowered, the outer ring 113b and the inner ring 113a are raised and lowered. The insulating member 115 is disposed to surround the lower electrode 111. The insulating member 115 is fixed to a bottom portion of the plasma processing chamber 10, to support the lower electrode 111.

The upper electrode 12 along with an insulating member 13 constitutes the plasma processing chamber 10. The upper electrode 12 supplies one or more types of processing gases from the gas supply 20 to the plasma processing space 10s. The upper electrode 12 includes a ceiling plate 121 and a support 122. A lower surface of the ceiling plate 121 defines the plasma processing space 10s. A plurality of gas introduction ports 121a is formed in the ceiling plate 121. Each of the plurality of gas introduction ports 121a penetrates through the ceiling plate 121 in a plate thickness direction (vertical direction) of the ceiling plate 121. The support 122 detachably supports the ceiling plate 121. A gas diffusion chamber 122a is provided inside the support 122. A plurality of gas introduction ports 122b extends downward from the gas diffusion chamber 122a. The plurality of gas introduction ports 122b communicates with the plurality of gas introduction ports 121a, respectively. The support 122 is provided with a gas supply port 122c. The upper electrode 12 supplies one or more processing gases from the gas supply port 122c to the plasma processing space 10s via the gas diffusion chamber 122a, the plurality of gas introduction ports 122b, and the plurality of gas introduction ports 121a.

A sidewall of the plasma processing chamber 10 is provided with a loading/unloading port 10p. The substrate W is transferred between the plasma processing space 10s and an outside of the plasma processing chamber 10 via the loading/unloading port 10p. The loading/unloading port 10p is opened and closed by a gate valve G.

The gas supply 20 includes one or more gas sources 21 and one or more flow rate controllers 22. The gas supply 20 supplies one or more types of processing gases from the respective gas sources 21 to the gas supply port 122c via the respective flow rate controllers 22. The flow rate controller 22 may include, for example, a mass flow controller or a pressure-controlled flow rate controller. The gas supply 20 may include one or more flow rate modulation devices that modulate or pulse flow rates of one or more processing gases.

The RF power supply 30 includes two RF power sources (a first RF power source 31a and a second RF power source 31b) and two matchers (a first matcher 32a and a second matcher 32b). The first RF power source 31a supplies first RF power to the lower electrode 111 via the first matcher 32a. A frequency of the first RF power may be, for example, 13 MHz to 150 MHz. The second RF power source 31b supplies second RF power to the lower electrode 111 via the second matcher 32b. A frequency of the second RF power may be, for example, 400 kHz to 13.56 MHz. Instead of the second RF power source 31b, a DC power source may be used.

The exhaust system 40 may be connected to, for example, a gas exhaust port 10e provided at the bottom portion of the plasma processing chamber 10. The exhaust system 40 may include a pressure adjusting valve and a vacuum pump. A pressure in the plasma processing space 10s is adjusted by the pressure adjusting valve. The vacuum pump may include a turbo molecular pump, a dry pump, or a combination thereof.

The lifter 50 includes a first lifter 51 and a second lifter 52.

The first lifter 51 includes a plurality of supporting pins 511 and an actuator 512. The plurality of supporting pins 511 is inserted into through-holes H1 formed in the lower electrode 111 and the electrostatic chuck 112 so as to be capable of protruding and retracting from an upper surface of the electrostatic chuck 112. The plurality of supporting pins 511 protrudes from the upper surface of the electrostatic chuck 112 to support the substrate W with upper ends of the plurality of supporting pins 511, which are in contact with a lower surface of the substrate W. The actuator 512 raises and lowers the plurality of supporting pins 511. As the actuator 512, for example, a motor such as a DC motor, a stepping motor, or a linear motor, an air driving mechanism such as an air cylinder, or a piezoelectric actuator may be used. For example, when transferring the substrate W between the transfer robot TR1 and the substrate support 11, the first lifter 51 raises and lowers the plurality of supporting pins 511.

The second lifter 52 includes the plurality of supporting pins 521 and an actuator 522. The supporting pin 521 is a stepped supporting pin formed of cylindrical (solid rod-shaped) members. The supporting pin 521 has a lower pin 523 and an upper pin 524. The upper pin 524 is installed on the lower pin 523. An outer diameter of the lower pin 523 is larger than an outer diameter of the upper pin 524. Accordingly, a stepped portion is formed by an upper end surface 523a of the lower pin 523. The lower pin 523 and the upper pin 524 are, for example, integrally formed.

The supporting pin 521 is inserted into a through-hole H11 formed in the lower electrode 111, a through-hole H12 formed in the insulating member 115, and a through-hole H13 formed in the outer ring 113b so as to be capable of protruding and retracting from the upper surface of the insulating member 115 and an upper surface of the outer ring 113b. Inner diameters of the through-holes H11 and H12 are slightly larger than the outer diameter of the lower pin 523. An inner diameter of the through-hole H13 is slightly larger than the outer diameter of the upper pin 524, and is smaller than the outer diameter of the lower pin 523.

The supporting pin 521 may be displaced between a standby position, a first support position, and a second support position.

The standby position is a position at which an upper end surface 524a of the upper pin 524 is below a lower surface of the inner ring 113a. When the supporting pin 521 is in the standby position, the inner ring 113a and the outer ring 113b are supported on the electrostatic chuck 112 and the insulating member 115, respectively, without being lifted by the supporting pin 521.

The first support position is a position above the standby position. The first support position is a position at which the upper end surface 524a of the upper pin 524 protrudes above the upper surface of the outer ring 113b, and the upper end surface 523a of the lower pin 523 is below a lower surface of the outer ring 113b. As the supporting pin 521 moves to the first support position, the upper end surface 524a of the upper pin 524 comes into contact with a recess formed in the lower surface of the inner ring 113a to support the inner ring 113a.

The second support position is a position above the first support position. The second support position is a position at which the upper end surface 523a of the lower pin 523 protrudes above the upper surface of the insulating member 115. As the supporting pin 521 moves to the second support position, the upper end surface 524a of the upper pin 524 comes into contact with the recess to support the inner ring 113a, and the upper end surface 523a of the lower pin 523 comes into contact with the lower surface of the outer ring 113b to support the outer ring 113b.

The actuator 522 raises and lowers the plurality of supporting pins 521. The actuator 522 may be configured similarly to the actuator 512.

When transferring the inner ring 113a between the transfer robot TR1 and the substrate support 11, the second lifter 52 lifts the inner ring 113a by moving the plurality of supporting pins 521 to the first support position. When transferring the inner ring 113a and the outer ring 113b between the transfer robot TR1 and the substrate support 11, the second lifter 52 lifts the inner ring 113a and the outer ring 113b by moving the plurality of supporting pins 521 to the second support position. Alternatively, even when transferring the outer ring 113b between the transfer robot TR1 and the substrate support 11 in a state in which the inner ring 113a does not exist, the second lifter 52 lifts the outer ring 113b by moving the plurality of supporting pins 521 to the second support position.

The controller 90 controls each part of the plasma processing apparatus 1. The controller 90 includes, for example, a computer 91. The computer 91 includes, for example, a CPU 911 which is a processor, a storage 912, and a communication interface 913. The CPU 911 is configured to perform various control operations, based on a program stored in the storage 912. The storage 912 includes at least one memory type selected from a group consisting of auxiliary storage devices such as a RAM, a ROM, a hard disk drive (HDD), and a solid state drive (SSD). The communication interface 913 may communicate with the plasma processing apparatus 1 via a communication line such as a local area network (LAN). The controller 90 may be provided separately from the controller CU or may be included in the controller CU.

### (Position Misalignment of Ring)

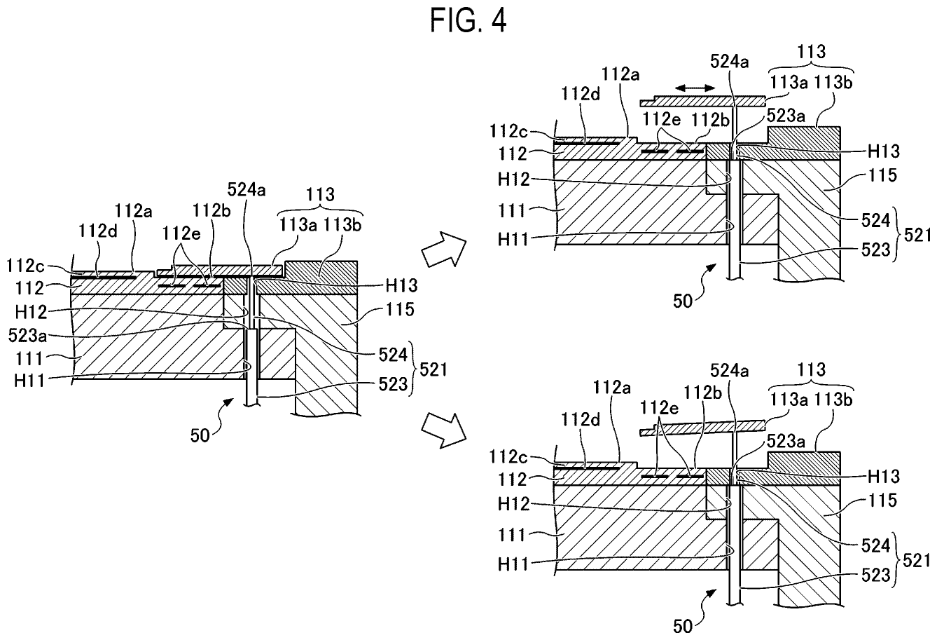

Next, a cause of a position misalignment which occurs in the ring 113 when taking out the ring 113 from the substrate support 11 is described with reference to FIG. 4.

In the processing modules PM1 to PM7 (e.g., the plasma processing apparatus 1 in FIG. 2), when processing the substrate W, the substrate W is electrostatically attracted and fixed by the electrostatic chuck 112. Further, in the plasma processing apparatus 1, at a periphery of the substrate W, the ring 113 (the inner ring 113a) is electrostatically attracted and fixed by the electrostatic chuck 112.

In the plasma processing apparatus 1, after a plasma processing, charges in the electrostatic chuck 112 are reduced by a charge removal processing (gas charge removal, plasma charge removal, or the like). Further, by applying a direct current voltage having a polarity different from that in the plasma processing to the electrostatic chuck 112 of the substrate support 11, electrostatic forces of the substrate support surface 112a and the ring support surface 112b may be reduced.

Although the charge removal processing is performed, charges may slightly remain in the substrate support surface 112a and the ring support surface 112b. Therefore, even after the charge removal processing, attraction of the inner ring 113a to the ring support surface 112b may slightly occur (hereinafter, also referred to as residual attraction). When the inner ring 113a is spaced apart from the ring support surface 112b by raising the supporting pins 521 so as to exchange the inner ring 113a, the inner ring 113a vibrates due to the residual attraction of the inner ring 113a, and hence the inner ring 113a is placed on the supporting pins 521 in a state in which the inner ring 113a is misaligned from a normal position of the inner ring 113a. Accordingly, there occurs a phenomenon in which the inner ring 113a is placed in a position misaligned from an original holding position (the supporting pins 521) at which the transfer robot TR1 holds the inner ring 113a.

For example, as illustrated in the upper right drawing of FIG. 4, the inner ring 113a may be misaligned in a horizontal direction (lateral direction). Accordingly, when transferring the inner ring 113a to the transfer robot TR1, the transfer robot TR1 holds the inner ring 113a at a misaligned position. The misaligned inner ring 113a may cause a problem such as that, in transfer of the transfer robot TR1, the inner ring 113a is broken due to interference with other parts.

Further, for example, as illustrated in the lower right drawing of FIG. 4, the position of the inner ring 113a is considerably misaligned due to the residual attraction, and therefore, the inner ring 113a may be obliquely inclined while getting out of some supporting pins 521 among the supporting pins 521. In this case, the transfer robot TR1 which slides in the horizontal direction above the substrate support 11 collides with the inner ring 113a, and therefore, the transfer robot TR1 and the inner ring 113a may be broken. That is, in the substrate processing system PS, it is required for the transfer robot TR1 to perform unloading or loading by suppressing the position misalignment of the inner ring 113a. However, in a conventional substrate processing system, when taking output an inner ring (edge ring) from a substrate support, whether a transfer robot held the inner ring at a normal position was not recognized.

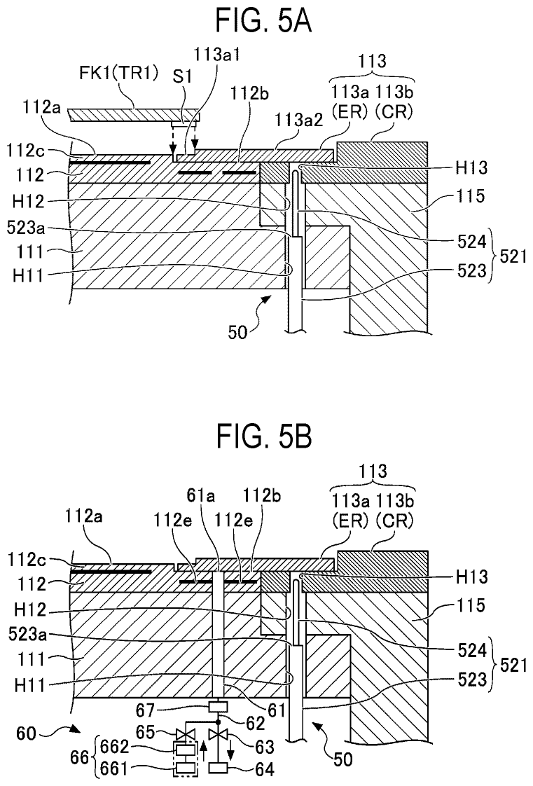

When unloading the inner ring 113a, the controller CU of the substrate processing system PS according to this embodiment acquires an index related to a position misalignment amount of the inner ring 113a. Further, when the position of the inner ring 113a is misaligned, the controller CU performs correction for resolving the position misalignment. Next, a configuration of acquiring an index related to a position misalignment amount of the inner ring 113a is described with reference to FIGS. 5A to 5C.

FIG. 5A is a view illustrating a first example of detecting an index related to a position misalignment amount of the inner ring 113a. The substrate processing system PS uses, as the index related to the position misalignment amount, a detection result of a position of the inner ring 113a detected by the position detection sensor S1 installed on the upper fork FK1 (or the position detection sensor S2 installed on the lower fork FK2). The position detection sensors S1 and S2 may be installed on a lower surface of the upper fork FK1 or the lower fork FK2, which faces the substrate support 11 (a surface opposite to a surface on which the substrate W is held). Further, a plurality of position detection sensors S1 or S2 may be installed at the upper fork FK1 or the lower fork FK2. For example, the position detection sensor S1 may be installed at each of two prong portions of the upper fork FK1. Further, an installation place of the position detection sensor S1 or S2 is not limited to the lower surface facing the substrate support 11 (the surface opposite to the surface on which the substrate W is held), and the position detection sensor S1 or S2 may be installed at a side surface of the upper fork FK1 or the lower fork FK2.

For example, an optical detector (e.g., a displacement sensor) capable of detecting a shape change of an object may be applied to the position detection sensors S1 and S2. The position detection sensor S1 or S2 detects an edge of the substrate support surface 112a by detecting a step difference between the substrate support surface 112a and the ring support surface 112b along with movement of the upper fork FK1 or the lower fork FK2 in the horizontal direction (left arrow of S1 in FIG. 5A). Further, an upper surface of the inner ring 113a includes an inner portion 113a1 lower than the substrate support surface 112a on an inner side in a radial direction and an outer portion 113a2 higher than the inner portion 113a1 on an outer at a diameter direction outer side of the inner portion 113a1. The position detection sensor S1 or S2 detects an edge of the inner ring 113a by detecting a step difference between the inner portion 113a1 and the outer portion 113a2 along with movement of the upper fork FK1 or the lower fork FK2 in the horizontal direction (right arrow of S1 in FIG. 5A). The controller CU may obtain a gap amount between the substrate support surface 112a and the inner ring 113a, based on a horizontal position (X coordinate and Y coordinate) of the edge of the substrate support surface 112a and a horizontal position (X coordinate and Y coordinate) of the edge of the inner ring 113a. The gap amount is a length of a gap in the horizontal direction between an inner peripheral surface of the inner portion 113a1 of the inner ring 113a and a sidewall between the substrate support surface 112a and the ring support surface 112b. For example, the gap amount is calculated as a value decomposed into an amount in an X-axis direction and an amount in a Y-axis direction.

The gap amount is specified in advance according to an outer diameter of the substrate support surface 112a and an inner diameter of the inner ring 113a. When there exists a portion of an annular gap, at which an absolute value of the gap amount is larger than a specified value, a position misalignment amount of the inner ring 113a becomes large. As such, the controller CU may calculate the position misalignment amount of the inner ring 113a with a high degree of precision, based on the detection result of the position detection sensor S1 or S2 (an example of the index related to the position misalignment amount).

FIG. 5B is a view illustrating a second example of detecting an index related to a position misalignment amount of the inner ring 113a. The substrate processing system PS may perform a gas leakage check between the ring support surface 112b and the inner ring 113a as the index related to the position misalignment amount.

That is, a gas supply port 61a is formed in the ring support surface 112b at a peripheral edge of the electrostatic chuck 112. The gas supply port 61a supplies a gas into a gap between a rear surface of the inner ring 113a placed on the ring support surface 112b and the ring support surface 112b. The gas may be the same as a heat transfer gas supplied to a bottom surface of the inner ring 113a in a plasma processing. As an example of the gas, He gas may be applied. Further, in a gas flow path 61 that communicates with the gas supply port 61a, an end portion of the gas flow path 61, which is opposite to the ring support surface 112b, is connected to a gas supply 66 via a pipe 62. The gas supply 66 may include one or more gas sources 661 and one or more flow rate controllers 662. In an embodiment, the gas supply 66 is configured to, for example, supply the gas from the gas source 661 to the gas supply port 61a via the flow rate controller 662. Each flow rate controller 662 may include, for example, a mass flow controller or a pressure-controlled flow rate controller. The gas flow path 61 and the pipe 62 may function as at least a portion of a supply path that supplies the gas between the ring support surface 112b and the rear surface of the inner ring 113a.

Further, the end portion of the gas flow path 61, which is opposite to the ring support surface 112b, is connected to an exhaust system 64 via the pipe 62. Accordingly, a periphery of the ring support surface 112b of the electrostatic chuck 112 may be exhausted via the gas supply port 61a. That is, the gas supply port 61a may function as an exhaust hole that exhausts the periphery of the ring support surface 112b. Therefore, in the embodiment, the gas flow path 61 and the pipe 62 may function as at least a portion of an exhaust path that exhausts the gap between the ring support surface 112b and the rear surface of the inner ring 113a.

Further, as for the electrostatic chuck 112, a pressure sensor 67 that measures a pressure of the gap between the inner ring 113a electrostatically attracted to the ring support surface 112b and the ring support surface 112b is provided. The pressure sensor 67 is, for example, installed in the pipe 62. Further, a switching valve 65 that switches execution and stop of gas supply by the gas supply 66 may be installed in the pipe 62. Similarly, a switching valve 63 that switches execution and stop of exhaust of the periphery of the ring support surface 112b by the exhaust system 64 may be installed in the pipe 62.

In a gas leakage check, the controller CU of the substrate processing system PS operates, for example, a gas check mechanism 60 (which including the gas flow path 61, the pipe 62, the switching valve 63, the exhaust system 64, the switching valve 65, the gas supply 66 and the pressure sensor 67) and the electrostatic chuck 112 according to a sequence described below. First, the controller CU applies a voltage to the second attraction electrode 112e of the electrostatic chuck 112 in a state in which the substrate W does not exist in the plasma processing chamber 10, the inner ring 113a is placed on the ring support surface 112b, and exhaust is performed via the gas flow path 61 by the exhaust system 64. Accordingly, a direct current voltage (e.g., direct current voltages having different polarities in the case of bipolar second attraction electrodes 112e) is applied to the second attraction electrode 112e of the electrostatic chuck 112.

Subsequently, the controller CU supplies a gas to the gas flow path 61 such that a pressure in the gas flow path 61 is maintained higher than a pressure in the plasma processing chamber 10. Specifically, the controller CU closes the switching valve 63 and stops the exhaust via the gas flow path 61 by the exhaust system 64. Meanwhile, the controller CU opens the switching valve 65 and supplies the gas by the gas supply 66. The gas is supplied into a gap between the rear surface of the inner ring 113a and the ring support surface 112b via the pipe 62 and the gas flow path 61. If a pressure in the gap becomes a target pressure (e.g., if a result measured by the pressure sensor 67 becomes the target pressure), the controller CU closes the switching valve 65 and stops the supply of the gas. The target pressure is, for example, the same as a pressure in the gap in the plasma processing.

After that, the controller CU measures a pressure in a flow path including the gas flow path 61 by the pressure sensor 67. Specifically, the pressure sensor 67 measures a pressure in the pipe 62 after a predetermined time elapses from the stop of the supply of the gas. The measured pressure is substantially the same as the pressure in the gap between the ring support surface 112b and the inner ring 113a. Therefore, the controller CU may determine leakage of the gas from the gap (an index related to a position misalignment amount of the inner ring 113a), based on the pressure measured by the pressure sensor 67. More specifically, the controller CU determines whether the measured pressure is less than a pressure threshold value as determination of gas leakage from the gap. The pressure threshold value is, for example, set to 90% to 98% of the target pressure, and information of the pressure threshold value is stored in advance in the storage 912. If the measured pressure is less than the pressure threshold value, the controller CU determines that the gas is leaked from the gap between the ring support surface 112b and the inner ring 113a, i.e., that the position of the inner ring 113a is misaligned.

FIG. 5C is a view illustrating a third example of detecting an index related to a position misalignment amount of the inner ring 113a. The controller CU acquires, as the index related to the position misalignment amount, image information of a camera CM installed on the upper fork FK1 or a camera CM installed on the lower fork FK2. The camera CM is, for example, installed on the lower surface of the upper fork FK1 or the lower fork FK2, which faces the substrate support 11, instead of the position detection sensors S1 and S2. Further, the camera CM may be installed on a side surface of the upper fork FK1 or the lower fork FK2.

In the image information, for example, a gap between the edge of the substrate support surface 112a and the edge of the inner ring 113a is included as color or contrast information. Therefore, the controller CU acquires image information imaged by the camera CM (an example of the index related to the position misalignment amount), and performs an appropriate image processing on the image information, so that it is possible to calculate a gap amount (position misalignment amount) with a high degree of precision.

Back to FIG. 1, the controller CU of the substrate processing system PS determines necessity of exchange of the inner ring 113a, based on a trigger such as an instruction by a user, a number of substrate processings, quality of the substrate W, a sensor value of each of the processing modules PM1 to PM7, or error occurrence. When determining that the exchange is necessary, the controller CU collects the inner ring 113a of the processing module for an exchange target, and performs a processing of exchanging the inner ring 113a with an inner ring 113a for exchange, which is accommodated in the ring accommodation module RSM. The inner ring 113a for exchange may be a new product (not used) or may be one that is completely used but is not consumed so much.

Further, when taking out the inner ring 113a from the processing module for the exchange target, the controller CU acquires an index related to a position misalignment amount of the inner ring 113a as described above to recognize whether a misalignment has occurred in the inner ring. Accordingly, it is possible to for the substrate processing system PS to correct the misalignment of the inner ring 113a, and thus it is possible to avoid damage of a part and the like.

### [Transfer Method]

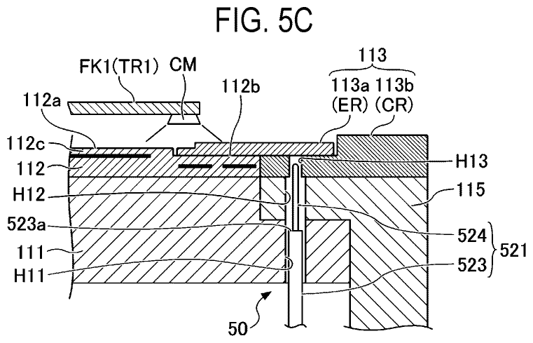

FIG. 6 is a flowchart illustrating an operation sequence when taking out an edge ring ER. Subsequently, an operation until taking out the edge ring ER is described with reference to FIG. 6. The edge ring ER corresponds to the inner ring 113a illustrated in FIGS. 3, 4 and 5A to 5C. Hereinafter, a case where the inner ring 113a is transferred between the processing module PM1 and the ring accommodation module RSM is described. Even in a case where a processing module for an exchange target is any one of the processing modules PM2 to PM7, the same method as a case where the processing module for the exchange target is the processing module PM1 may be used.

The operation sequence includes steps S1 to S6. The steps S1 to S6 are performed as the controller CU and/or the controller 90 controls each part of the substrate processing system PS. Although the controller CU is described separately from the controller 90, the controller CU may have functions of the controller 90 to control all processings, and the controller 90 may have functions of the controller CU to control all processings.

In the step S1, the controller CU controls the plasma processing apparatus 1 constituting the processing module PM1 to perform a plasma processing (substrate processing) on the substrate W in the plasma processing chamber 10. In the plasma processing, the controller 90 of the plasma processing apparatus 1 attracts the substrate W and the edge ring ER by applying a direct current voltage to the first attraction electrode 112d and the second attraction electrode 112e of the electrostatic chuck 112.

Then, after the plasma processing, the controller CU unloads the substrate W in the plasma processing apparatus 1 by the transfer robot TR1. At this time, the controller 90 stops the application of the direct current voltage to the first attraction electrode 112d (or applies another direct current voltage having a polarity different from a polarity of the direct current voltage) and enables the substrate W to be taken out. The controller 90 raises the substrate W by the first lifter 51 and transfers the substrate W to the transfer robot TR1 which enters into the plasma processing chamber 10. The transfer robot TR1 unloads the substrate W from the plasma processing apparatus 1, and transfers the substrate W to a next processing module or any one of the load lock modules LL1 to LL3.

In the step S2, after unloading the substrate W, the controller CU controls the plasma processing apparatus 1 to operate in an idle mode. The idle mode is a mode after the substrate W is plasma-processed, and is a mode in which the plasma processing is not performed. In the idle mode, the controller CU determines necessity of exchange of the edge ring ER, and determines whether the exchange of the edge ring ER can be performed. Necessity of exchange of the ring 113 may be determined based on the above-described trigger. The controller CU determines whether the exchange can be performed, based on existence of the substrate W in the processing module PM1 for the exchange target, a transfer schedule of the transfer robot TR1, or the like. Further, in the step S2, the controller 90 keeps attracting the inner ring 113a by applying the direct current voltage to the second attraction electrode 112e. The determination of the exchange of the edge ring ER is not limited to that in the idle mode, and may be performed at another timing such as a plasma processing.

When determining that the exchange of the inner ring 113a is performed, in the step S3, the controller CU controls the plasma processing apparatus 1 to perform a charge removal processing on the inner ring 113a. For example, when performing a gas charge removal processing in the charge removal processing, the plasma processing apparatus 1 controls the plasma processing chamber 10 at a predetermined pressure by supplying an inert gas such as N₂ gas into the plasma processing chamber 10 by the gas supply 20, and exhausting a gas in the plasma processing chamber 10 by the exhaust system 40. Further, the plasma processing apparatus 1 applies a direct current voltage having a polarity different from a polarity of the direct current voltage applied in the plasma processing to the second attraction electrode 112e of the electrostatic chuck 112 for a predetermined time, and then stops. Further, the plasma processing apparatus 1 stops the pressure control and ends the gas charge removal.

Further, in the steps S4 to S6, the controller CU transfers the edge ring ER from the processing module PM1 to the ring accommodation module RSM. First, a case where state identification and transfer of the edge ring ER is performed by the position detection sensor S1 or S2 of the transfer robot TR1 illustrated in FIG. 5A (hereinafter, also referred to as a transfer method according to a first example) is described.

In the step S4, in a case where the controller CU identifies a misalignment of the inner ring 113a when raising the inner ring 113a from the substrate support 11, the controller CU performs a misalignment identification and correction processing of correcting the misalignment.

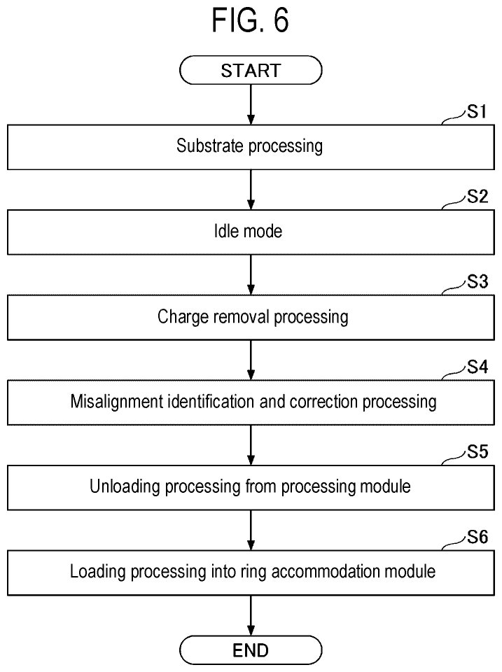

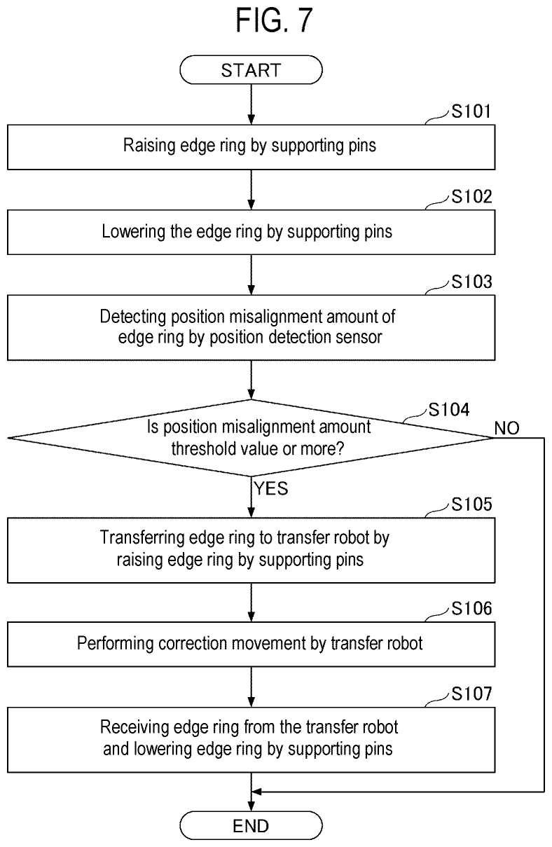

FIG. 7 is a flowchart illustrating a processing flow of the misalignment identification and correction processing. FIGS. 8A to 8F are views illustrating an operation of the misalignment identification and correction processing. In the misalignment identification and correction processing, first, the controller CU raises the supporting pins 521 of the plasma processing apparatus 1 and separates the edge ring ER from the ring support surface 112b of the substrate support 11 (step S101 in FIG. 7). When residual attraction exists between the ring support surface 112b and the edge ring ER, a misalignment may occur in the edge ring ER when raised as illustrated in FIG. 8A.

The controller CU lowers the supporting pins 521 of the plasma processing apparatus 1 and temporarily places the edge ring ER on the ring support surface 112b of the substrate support 11 for the time being (step S102 in FIG. 7). When the misalignment of the edge ring ER occurs, the edge ring ER is disposed while being misaligned from the substrate support surface 112a as illustrated in FIG. 8B.

Subsequently, the controller CU operates the transfer robot TR1 and detects a position of the edge ring ER (an example of an index related to a position misalignment amount) by the position detection sensor S1 or S2 (step S103 in FIG. 7). For example, as illustrated in FIG. 8C, the transfer robot TR1 moves in the horizontal direction within the plasma processing space 10s to dispose the position detection sensor S1 or S2 at a position capable of detecting an edge of the substrate support surface 112a and an edge of the edge ring ER. Accordingly, the controller CU receives a detection result of the position detection sensor S1 or S2, thereby obtaining gap amounts (position misalignment amounts) of the substrate support surface 112a and the edge ring ER.

Subsequently, the controller CU determines whether the position misalignment amount of the edge ring ER is a pre-stored threshold value or more by comparing the position misalignment amount of the edge ring ER with the threshold value (step S104). The threshold value may be set to an appropriate value according to a measurement of the substrate support surface 112a or the edge ring ER, and may be set to, for example, a value in a range of about 0.1 mm to about 0.4 mm. In this embodiment, the threshold value is set to 0.15 mm.

If the position misalignment amount is less than the threshold value (the step S104: “NO”), the edge ring ER may not be misaligned (or the position misalignment amount may be sufficiently small). Therefore, the controller CU ends the misalignment identification and correction processing (the step S4 in FIG. 6), and proceeds to the step S5. Meanwhile, if the position misalignment amount is the threshold value or more (the step S104: “YES”), it may be determined that the edge ring ER is misaligned (or the position misalignment amount is large). In this case, the controller CU detects an error of the edge ring ER, and proceeds to step S105 in FIG. 7.

In the step S105, the controller CU raises the edge ring ER by the supporting pins 521 of the plasma processing apparatus 1, and enters the transfer robot TR1 into the plasma processing space 10s to transfer the edge ring ER. Accordingly, as illustrated in FIG. 8D, the edge ring ER is held by the transfer robot TR1 in a state in which the edge ring ER is misaligned.

After that, the controller CU performs a correction movement of correcting the misalignment of the edge ring ER by the transfer robot TR1 that holds the edge ring ER (step S106 in FIG. 7). In a configuration that detects the misalignment of the edge ring ER by the position detection sensor S1 or S2, in the step S103, the position misalignment amount of the edge ring ER has already been acquired. Therefore, as illustrated in FIG. 8E, the controller CU sets a movement amount in the correction movement of the transfer robot TR1 based on the acquired position misalignment amount, and horizontally moves the transfer robot TR1 by the movement amount. In the example of FIG. 8E, the transfer robot TR1 is horizontally moved in a right direction by the movement amount. As a result, the edge ring ER is returned to a normal position above the substrate support 11.

The controller CU receives the edge ring ER from the transfer robot TR1 by the supporting pins 521, and places the edge ring ER on the ring support surface 112b again by lowering the supporting pins 521 after withdrawal of the transfer robot TR1 (step S107 in FIG. 7). Accordingly, as illustrated in FIG. 8F, the edge ring ER is supported on the ring support surface 112b in a state in which the position misalignment is resolved. When the step S107 is ended, the misalignment identification and correction processing (step S4) is ended. Further, after receiving the edge ring ER by the supporting pins 521, the controller CU may perform an unloading processing of unloading the edge ring ER from the processing module PM1 without lowering the supporting pins 521.

Back to FIG. 6, in the step S5, the controller CU performs an unloading processing of unloading the edge ring ER from the processing module PM1. Specifically, the controller CU raises the edge ring ER by the supporting pins 521 of the plasma processing apparatus 1 and receives the edge ring ER via the transfer robot TR1. After placing the edge ring ER (after the step S107), electrostatic attraction by the electrostatic chuck 112 is not performed. Therefore, when raising the edge ring ER by the supporting pins 521, the edge ring ER may be disposed without being misaligned from a holding position of the transfer robot TR1. The transfer robot TR1 receives the edge ring ER in which no misalignment occurs, and unloads the edge ring ER from the processing module PM1 after the lowering of the supporting pins 521. At this time, the transfer robot TR1 may smoothly unload the edge ring ER without interfering with other parts.

In the step S6, the controller CU performs a loading processing of loading the edge ring ER into the ring accommodation module RSM by transferring the edge ring ER by the transfer robot TR1. Since the transfer robot TR1 holds the edge ring ER in which no misalignment occurs, it is possible to stably transfer the edge ring ER into the ring accommodation module RSM without interfering with other parts of the ring accommodation module RSM or the like.

As described above, in the substrate processing system PS and the transfer method, a misalignment of the edge ring ER is identified when unloading the edge ring ER from the processing module PM1, and a correction is performed when the misalignment occurs. Therefore, it is possible to transfer the edge ring ER without interfering with other parts. Accordingly, it is possible to prevent the edge ring ER from dropping off the transfer robot TR1, and to avoid damage to the edge ring ER or other parts, and the like. Thus, it is possible to for the substrate processing system PS to reduce an opportunity for stopping the substrate processing system PS for performing a maintenance.

Further, the substrate processing system PS and the transfer method are not limited to the embodiment, and may have various modifications. For example, the transfer method illustrated in FIG. 6 has described a case where only the edge ring ER is exchanged, but may be applied even in a case where a cover ring CR (the outer ring 113b) is exchanged. By performing a misalignment identification and correction processing even when unloading the cover ring CR, it is possible to stably transfer the cover ring CR.

The substrate support 11 of each of the processing modules PM1 to PM7 is not limited to a configuration that electrostatically attracts the substrate W and the ring 113 by the electrostatic chuck 112. For example, the substrate support 11 may employ a mechanism that provides an attractive force to the substrate W and the ring 113, a mechanism that mechanically hangs and fixes the ring 113, or the like. In this case, since the ring 113 is adhered to the ring support surface 112b or other parts, the ring 113 may be misaligned when the supporting pins 521 are raised. Thus, it is possible for the substrate processing system PS to transfer the ring 113 while suppressing the misalignment of the ring 113 by performing the transfer method according to the embodiment.

In addition, in the misalignment identification and correction processing, after placing the edge ring ER on the ring support surface 112b in the step S102, the index related to the position misalignment amount of the edge ring ER is acquired by the position detection sensor S1 or S2 of the transfer robot TR1. However, in the misalignment identification and correction processing, the index related to the position misalignment amount of the edge ring ER may be acquired by the position detection sensor S1 or S2 of the transfer robot TR1 in a state in which the edge ring ER is supported (raised) by the supporting pins 521.

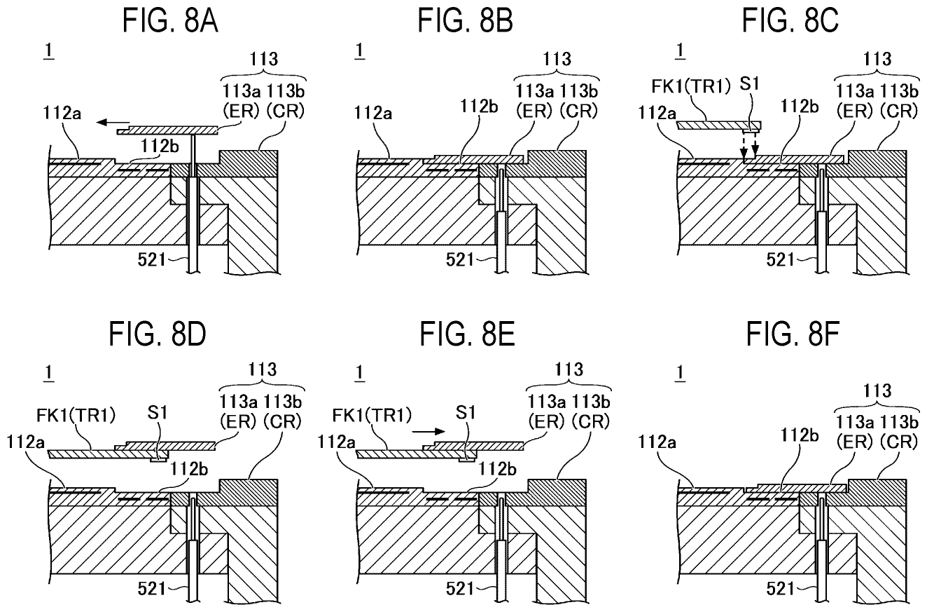

For example, as illustrated in FIG. 9, in step S111, the controller CU raises the edge ring ER by the supporting pins 521, and stops the supporting pins 521 at a timing at which the edge ring ER is separated from the ring support surface 112b. Further, the controller CU acquires a position misalignment amount by the position detection sensors S1 and S2 in a state in which the supporting pins 521 are stopped. Alternatively, the controller CU may acquire a position misalignment amount by the position detection sensors S1 and S2 at an arbitrary pin height which is higher than the position at which the edge ring ER is separated from the ring support surface 112b and at which the upper surface of the edge ring ER is below the position detection sensors S1 and S2 of the transfer robot TR1. In step S112, the controller CU detects a position misalignment amount of the edge ring ER by the position detection sensor S1 or S2. In step S113, the controller CU determines whether the position misalignment amount of the edge ring ER is a threshold value or more. Further, if the position misalignment amount is the threshold value or more (the step S113: “YES”), the controller CU raises the edge ring ER to a transfer height by the supporting pins 521 and enters the transfer robot TR1 into the plasma processing space 10s to transfer the edge ring ER (step S114). In step S115, the controller CU performs a correction movement of correcting a misalignment of the edge ring ER by the transfer robot TR1 that holds the edge ring ER. Further, in step S116, the controller CU receives the edge ring ER from the transfer robot TR1 by the supporting pins 521, and places the edge ring ER on the ring support surface 112b again by lowering the supporting pins 521 after withdrawal of the transfer robot TR1. Accordingly, operations of lowering the edge ring ER in the step S102 in FIG. 7 and raising the edge ring ER in the step S105 in FIG. 7 may be omitted, thus more efficiently performing a processing. Further, in the step S115, the controller CU may move and correct the transfer robot TR1 in consideration of the position misalignment amount of the edge ring ER, and then receive the edge ring ER and unload the edge ring ER as it is. Accordingly, the step S116 may be omitted.

In addition, in the misalignment identification and correction processing, the misalignment of the edge ring ER has been resolved by receiving the edge ring ER by the transfer robot TR1, and then performing the correction movement. However, in the misalignment identification and correction processing, before the transfer robot TR1 receives the edge ring ER held by the supporting pins 521 in the step S105 in FIG. 7, the transfer robot TR1 may be corrected and moved in advance by the position misalignment amount, and then the edge ring ER may be transferred to the transfer robot TR1. Accordingly, for example, the step S106 or S107 in FIG. 7 may be omitted, thus much more efficiently performing a processing.

In addition, in the misalignment identification and correction processing (the step S4), the substrate processing system PS may perform a cleaning processing in the plasma processing chamber 10 by stopping at a predetermined height while raising the edge ring ER by the supporting pins 521, may perform the cleaning processing in the plasma processing chamber 10 after raising the supporting pins 521 to the transfer height, or may perform the cleaning processing in the plasma processing chamber 10 while raising the edge ring ER. Alternatively, in the unloading processing from any one of the processing modules PM1 to PM7 (the step S5), the substrate processing system PS may perform the cleaning processing in the plasma processing chamber 10 by stopping at a predetermined height while raising the edge ring ER by the supporting pins 521, may perform the cleaning processing in the plasma processing chamber 10 after raising the supporting pins 521 to the transfer height, or may perform the cleaning processing in the plasma processing chamber 10 while raising the edge ring ER. The cleaning processing may use, for example, a method such as wafer-less dry cleaning (WLDC) or a wafer with dry cleaning (WWDC) performed by placing, on the substrate support 11, a dummy wafer that has a diameter smaller than the diameter of the substrate W and equal to the diameter of the substrate support surface 112a. In the case of the WWDC, the dummy wafer having the same diameter as the substrate support surface 112a is placed on the substrate support 11 until before the steps S4 and S5.

In addition, from after the substrate processing in the step S1 to the charge removal processing in the step S3, the substrate processing system PS may perform wafer-less dry cleaning, or may perform dry cleaning by placing a dummy wafer having the same diameter as the substrate W or a dummy wafer having a diameter smaller than the diameter of the substrate W and equal to the diameter of the substrate support surface 112a. Further, before the ring for exchange is loaded after the step S5, the substrate processing system PS may perform wafer-less dry cleaning, or may perform dry cleaning by placing a dummy wafer having the same diameter as the substrate W or a dummy wafer having a diameter smaller than the diameter of the substrate W and equal to the diameter of the substrate support surface 112a.

The cleaning processing is performed in the misalignment identification and correction processing or the unloading processing, so that it is possible to clean the edge ring ER before unloading the edge ring ER to the vacuum transfer chamber, thereby suppressing the vacuum transfer chamber from being contaminated by a deposit attached to the edge ring ER. In addition, the cleaning processing is performed at a timing at which the edge ring ER is raised, so that it is possible to remove a deposit attached to the ring support surface 112b. In addition, the substrate processing system PS performs the cleansing processing on the edge ring ER during an unloading operation, so that it is possible to improve a throughput of the entire processing as compared with a case where the cleaning processing is separately performed. In addition, the deposit attached to the ring support surface is removed by performing the cleaning processing after the edge ring is unloaded and before the edge ring for exchange is loaded, so that it is possible to suppress an attraction failure of the edge ring for exchange.

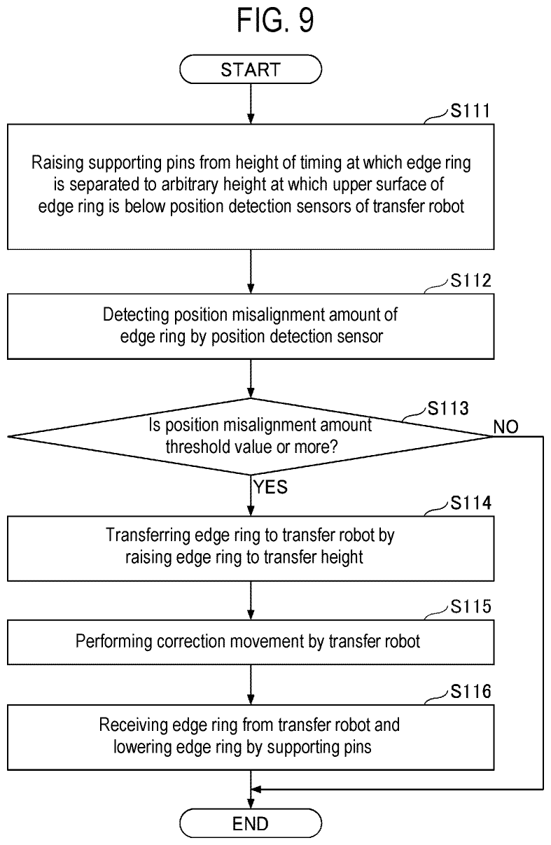

FIG. 10 is a flowchart illustrating a transfer method according to a second example. The transfer method according to the second example performs state identification and transfer of the edge ring ER by the position detection sensor S1 or S2 of the transfer robot TR1. Further, in description of the transfer method according to the second example, a case where the ring 113 is transferred between the ring accommodation module RSM and the processing module PM1 is described in detail. Even in a case where a processing module for an exchange target is any one of the processing modules PM2 to PM7, the same method as a case where the processing module for the exchange target is the processing module PM1 may be used.

When performing the steps to the step S3 in the operation sequence in FIG. 6, the controller CU of the substrate processing system PS performs steps S201 to S210 as the transfer method according to the second example. The steps S201 to S210 are performed as the controller CU controls each part of the substrate processing system PS.

The steps S201 to S204 may be the same as the steps S101 to S104. However, if a position misalignment amount of the edge ring ER is a threshold value or more in the step S204 (the step S204: “YES”), the controller CU may proceed to the step S205. If the position misalignment amount of the edge ring ER is less than the threshold value, the controller CU may proceeds to the step S208 (the step S204: “NO”).

In the step S205, the controller CU raises the edge ring ER by the supporting pins 521, enters the transfer robot TR1 into the plasma processing space 10s, and then lowers the supporting pins 521 to transfer the edge ring ER to the transfer robot TR1. Accordingly, the edge ring ER is held by the transfer robot TR1 in a state in which the edge ring ER is misaligned.

After that, the controller CU performs an unloading processing of unloading the edge ring ER from the processing module PM1 (the step S206). By performing the unloading processing after the step S205, the transfer robot TR1 unloads the edge ring ER from the processing module PM1 while holding the edge ring ER in the state in which the edge ring ER is misaligned.

Further, the controller CU performs a loading processing of loading the edge ring ER into the ring accommodation module RSM by transferring the edge ring ER by the transfer robot TR1 (the step S207). In the loading processing, when loading the edge ring ER into an accommodation module (e.g., a cassette which is not illustrated) of the ring accommodation module RSM, the controller CU sets a movement amount of the transfer robot TR1, based on the position misalignment amount acquired in the step S203, and corrects and moves the transfer robot TR1. Accordingly, the edge ring ER is returned to the normal position by the transfer robot TR1 without interfering with the ring accommodation module RSM. Thus, the controller CU may smoothly accommodate the edge ring ER without interfering with other parts.

Meanwhile, if the position misalignment amount is less than the threshold value, the edge ring ER may not be misaligned (or the position misalignment amount may be sufficiently small), and hence the controller CU performs ordinary transfer (of not performing movement and correction) in the steps S208 to S210.

Specifically, the controller CU raises the edge ring ER by the supporting pins 521 of the plasma processing apparatus 1 and enters the transfer robot TR1 into the plasma processing space 10s to transfer the edge ring ER (the step S208). Further, the controller CU performs an unloading processing of unloading the edge ring ER from the processing module PM1 (the step S209). Further, the controller CU transfers the edge ring ER by the transfer robot TR1, and loads the edge ring ER into the ring accommodation module RSM (the step S210). When loading the edge ring ER into the ring accommodation module RSM, the transfer robot TR1 may accommodate the edge ring ER in the accommodation module without moving and correcting the edge ring ER. That is, the unloading processings in the steps S206 and S209 correspond to the unloading processing in the step S5 in FIG. 6, and the loading processings in the steps S207 and S210 correspond to the loading processing in the step S6 in FIG. 6.

As such, in a case where the edge ring ER is misaligned, the transfer method according to the second example performs movement and correction when the edge ring ER is loaded into the ring accommodation module RSM, thus suppressing interference between the edge ring ER and other parts. Further, the transfer method according to the second example may also have various modifications. For example, in the misalignment identification and correction processing, an index related to a position misalignment amount of the edge ring ER may be acquired by the position detection sensor S1 or S2 of the transfer robot TR1 in a state in which the edge ring ER is supported by the supporting pins 521. That is, in the step S201, the controller CU may stop the supporting pins 521 at a position at which the edge ring ER is separated from the ring support surface 112b and then acquire a position misalignment amount by the position detection sensor S1 or S2, or may acquire a position misalignment amount by the position detection sensors S1 and S2, at an arbitrary pin height which is higher than the position at which the edge ring ER is separated from the ring support surface 112b and at which the upper surface of the edge ring ER is below the position detection sensors S1 and S2 (see FIG. 9).

Further, the controller CU may select implementation of the transfer method according to the first example or implementation of the transfer method according to the second example based on the position misalignment amount of the edge ring ER. For example, the controller CU has a threshold value for selection of a transfer method, and may determine the transfer method according to the first example if the position misalignment amount is equal to or larger than the threshold value for selection, or may determine the transfer method according to the second example if the position misalignment amount is less than the threshold value for selection. The threshold value for selection is a value larger than a threshold value for determining movement and correction. Accordingly, when the position misalignment amount of the edge ring ER is large, a misalignment of the edge ring ER is corrected in the processing module PM1, so that more stable transfer is possible. Meanwhile, when the position misalignment amount of the edge ring ER is small even though movement and correction is necessary, a misalignment of the edge ring ER is corrected when the edge ring ER is transferred to the ring accommodation module RSM, so that it is possible to improve transfer efficiency.

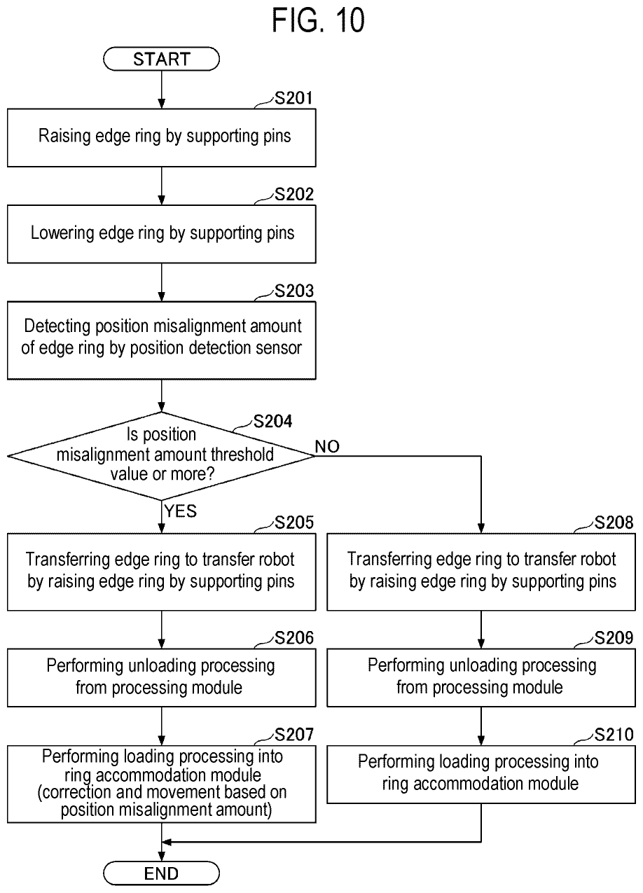

The substrate processing system PS is not limited to a configuration of loading the ring 113 (the edge ring ER) in any one of the processing modules PM1 to PM7 directly into the ring accommodation module RSM by the transfer robot TR1. The substrate processing system PS may transfer an upper ring 222 of a ring 220 to a standby transfer module LM, for example, when a plasma processing apparatus 1A shown in FIG. 11 is applied. FIG. 11 is a schematic cross-sectional view illustrating another example of the plasma processing apparatus.

The plasma processing apparatus 1A shown in FIG. 11 is different from the plasma processing apparatus 1 in that the plasma processing apparatus 1A includes a substrate support 16 instead of the substrate support 11 and includes a ring assembly 220 (ring 220) instead of the ring assembly 113. Other parts may be the same as the plasma processing apparatus 1. Hereinafter, differences from the plasma processing apparatus 1 are mainly described.

The plasma processing apparatus 1A includes the substrate support 16. The substrate support 16 is installed inside the plasma processing chamber 10. The substrate support 16 supports a substrate W. The substrate support 16 is supported by a support 17. The support 17 extends upward from a bottom portion of the plasma processing chamber 10. The support 17 has a cylindrical shape. The support 17 is made of an insulating material such as quartz.

The substrate support 16 has a first region 161 and a second region 162. The first region 161 supports the substrate W. The first region 161 is a substantially circular region in a plan view. The first region 161 may include a base 18 and an electrostatic chuck 19. The first region 161 may be configured by a portion of the base 18 and a portion of the electrostatic chuck 19. The base 18 and the electrostatic chuck 19 are installed inside the plasma processing chamber 10. The base 18 is made of a conductive material such as aluminum. The base 18 has a substantially disk shape. The base 18 constitutes a lower electrode.

The substrate support 16 includes a main body 2 and the ring assembly 220. The main body 2 includes the base 18 and the electrostatic chuck 19. The main body 2 has a substrate support region 2a for supporting the substrate W, an annular region 2b for supporting the ring assembly 220, and a sidewall 2c that extends vertically between the substrate support region 2a and the annular region 2b. The annular region 2b surrounds the substrate support region 2a. The annular region 2b is located below the substrate support region 2a. Therefore, an upper end of the sidewall 2c is connected to the substrate support region 2a, and a lower end of the sidewall 2c is connected to the annular region 2b.

A flow path 18f is formed in the base 18. The flow path 18f is a flow path through which a heat exchange medium flows. As the heat exchange medium, a liquid refrigerant or a refrigerant (e.g., chlorofluorocarbon) that cools the base 18 by vaporization of the liquid refrigerant is used. A supply device of the heat exchange medium (e.g., a chiller unit) is connected to the flow path 18f. The supply device is installed outside the plasma processing chamber 10. The heat exchange medium is supplied to the flow path 18f from the supply device. The heat exchange medium supplied to the flow path 18f is returned to the supply device.

The electrostatic chuck 19 is installed on the base 18. The substrate W is placed on the first region 161 and on the electrostatic chuck 19 when processed in the plasma processing chamber 10.

The second region 162 extends radially outward from the first region 161 to surround the first region 161. The second region 162 is a substantially annular region in a plan view. The ring assembly 220 is placed on the second region 162. The second region 162 may include the base 18. The second region 162 may include the electrostatic chuck 19. The second region 162 may be composed of another portion of the base 18 and another portion of the electrostatic chuck 19. The substrate W is placed in a region surrounded by the ring assembly 220 and on the electrostatic chuck 19. Details of the ring assembly 220 will be described later.

A through-hole 162h is formed in the second region 162. The main body 2 has the through-hole 162h formed between the annular region 2b and a lower surface 2d of the main body 2. The through-hole 162h is formed in the second region 162 to extend along a vertical direction. A plurality of through-holes 162h are formed in the second region 162. A number of the through-holes 162h may be equal to a number of lift pins 72 of a lift mechanism 70 which will be described later. Each through-hole 162h is disposed parallel with a corresponding lift pin 72 on a straight line.

The electrostatic chuck 19 includes a main body 19m and an electrode 19e. The main body 19m is made of a dielectric such as aluminum oxide or aluminum nitride. The main body 19m has a substantially disk shape. The electrode 19e is installed in the main body 19m. The electrode 19e has a film shape. A direct current power source is electrically connected to the electrode 19e via a switch. When a voltage from the direct current power source is applied to the electrode 19e, an electrostatic attraction force is generated between the electrostatic chuck 19 and the substrate W. By the generated electrostatic attraction force, the substrate W is attracted to the electrostatic chuck 19 and held by the electrostatic chuck 19.

The plasma processing apparatus 1A further includes an outer peripheral member 27. The outer peripheral member 27 extends circumferentially and radially outward from the substrate support 16 to surround the substrate support 16. The outer peripheral member 27 may extend circumferentially and radially outward from the support 17 to surround the support 17. The outer peripheral member 27 may be composed of one or more parts. The outer peripheral member 27 may be formed of an insulating material such as quartz.

The ring assembly 220 and the substrate support 16 will now be described in more detail. The ring assembly 220 includes a lower ring 221 and an upper ring 222.

Each of the lower ring 221 and the upper ring 222 has an annular shape. Each of the lower ring 221 and the upper ring 222 is formed of a material appropriately selected according to a plasma processing performed in the plasma processing apparatus 1A. Each of the lower ring 221 and the upper ring 222 is formed of, for example, silicon or silicon carbide.

The lower ring 221 is disposed on the annular region 2b. The lower ring 221 may be placed on the second region 162 and on the electrostatic chuck 19. The lower ring 221 may be placed on a part other than the electrostatic chuck 19 in the second region 162.

A lower surface of the upper ring 222 is substantially flat. The lower surface of the upper ring 222 includes a tapered surface and defines a recess. The lower surface of the upper ring 222 defines a plurality of recesses. A number of tapered surfaces of the upper ring 222 and a number of recesses may be the same as the number of lift pins 72 of the lift mechanism 70. Each recess has a size in which a tip end of a second rod portion 722 of a corresponding lift pin 72 is fitted into the recess. The upper ring 222 is disposed on the lower ring 221 such that each recess is aligned with corresponding lift pins 72 and corresponding through-holes 221h on a straight line.

The upper ring 222 is accommodated in a recess of the lower ring 221. The lower ring 221 and the upper ring 222 are configured such that when disposed on the annular region 2b, an upper surface of an outer portion of the lower ring 221 and an upper surface of the upper ring 222 are substantially at the same height as an upper surface of the substrate W on the substrate support region 2a. The upper ring 222 includes an inner peripheral surface 222a that faces an end surface of the substrate W on the substrate support region 2a when the lower ring 221 and the upper ring 222 are disposed on the annular region 2b.

The substrate support 16 includes the lift mechanism 70. The lift mechanism 70 includes the lift pins 72, and is configured to raise and lower the lower ring 221 and the upper ring 222. The lift mechanism 70 includes a plurality of lift pins 72. The number of lift pins 72 may be any number as long as the lift pins 72 are capable of supporting, raising and lowering the ring assembly 220. The number of lift pins 72 may be, for example three.

Each lift pin 72 may be formed of an insulating material. Each lift pin 72 may be formed of, for example, sapphire, alumina, quartz, silicon nitride, aluminum nitride, or resin. Each lift pin 72 includes a first rod portion 721 and the second rod portion 722. The first rod portion 721 extends in the vertical direction. The first rod portion 721 includes a first upper end surface 721t. The first upper end surface 721t may come in contact with a lower surface of the lower ring 221.

The second rod portion 722 extends vertically upward from the first rod portion 721. The second rod portion 722 is narrowed with respect to the first rod portion 721 to expose the first upper end surface 721t. Each of the first rod portion 721 and the second rod portion 722 has a columnar shape. A diameter of the first rod portion 721 is larger than a diameter of the second rod portion 722. The second rod portion 722 is capable of moving up and down through the through-hole 221h. A length of the second rod portion 722 in the vertical direction is longer than a vertical thickness of a region of the lower ring 221 on which the upper ring 222 is placed.

The second rod portion 722 has a second upper end surface 722t. The second upper end surface 722t may come in contact with the upper ring 222. The tip end of the second rod portion 722 including the second upper end surface 722t may be formed in a tapered shape to be fitted into a corresponding recess in the upper ring 222.

The second rod portion 722 may include a first portion 722a and a second portion 722b. The first portion 722a has a columnar shape and extends upward from the first rod portion 721. The second portion 722b has a columnar shape and extends upward from the first portion 722a. The second portion 722b includes the second upper end surface 722t. A width of the first portion 722a is larger than a width of the second portion 722b.

The first rod portion 721, the first portion 722a, and the second portion 722b may have a columnar shape. A diameter of the first rod portion 721 is larger than a diameter of the first portion 722a, and the diameter of the first portion 722a is larger than a diameter of the second portion 722b.

The second rod portion 722 may include a third portion 722c. The third portion 722c extends between the first portion 722a and the second portion 722b. The third portion 722c has a tapered surface.

The lift mechanism 70 includes one or more drives 74. The one or more drives 74 are configured to raise and lower the plurality of lift pins 72. Each of the one or more drives 74 may include, for example, a motor.

For example, the upper ring 222 is stored in a ring accommodation container CS2 loaded into the load port LP4 of the atmospheric transfer module LM. The ring accommodation container CS2 corresponds to a ring accommodation module. The controller CU unloads the upper ring 222 of any one of the processing modules PM1 to PM7 to the vacuum transfer module TM, and transfers the upper ring 222 to any one of the load lock modules LL1 to LL3. Further, when unloading the upper ring 222 from any one of the load lock modules LL1 to LL3 using the transfer robot TR2 of the atmospheric transfer module LM, the controller CU loads and accommodate the upper ring 222 in the ring accommodation container CS2.

Correction and movement when a position misalignment occurs in the upper ring 222 may be performed in any one of the processing modules PM1 to PM7, or may be performed when the transfer robot TR1 loads and places the upper ring 222 in any one of the load lock modules LL1 to LL3. Alternatively, the correction and movement may be performed when the transfer robot TR2 of the atmospheric transfer module LM loads the upper ring 222 into the ring accommodation container CS2. Further, in the transfer method, the same processing as above may be performed even when transferring the lower ring 221 in addition to the upper ring 222. In addition, for example, the processing modules PM1 to PM7 of the substrate processing system PS are not limited to the ring assemblies 113 and 220 including a combination of a plurality of members, and may be configured to use a ring including one member. In this case, the transfer methods according to the first and second examples may be applied, and transfer methods according to third to fifth examples, which will be described later, may be applied.

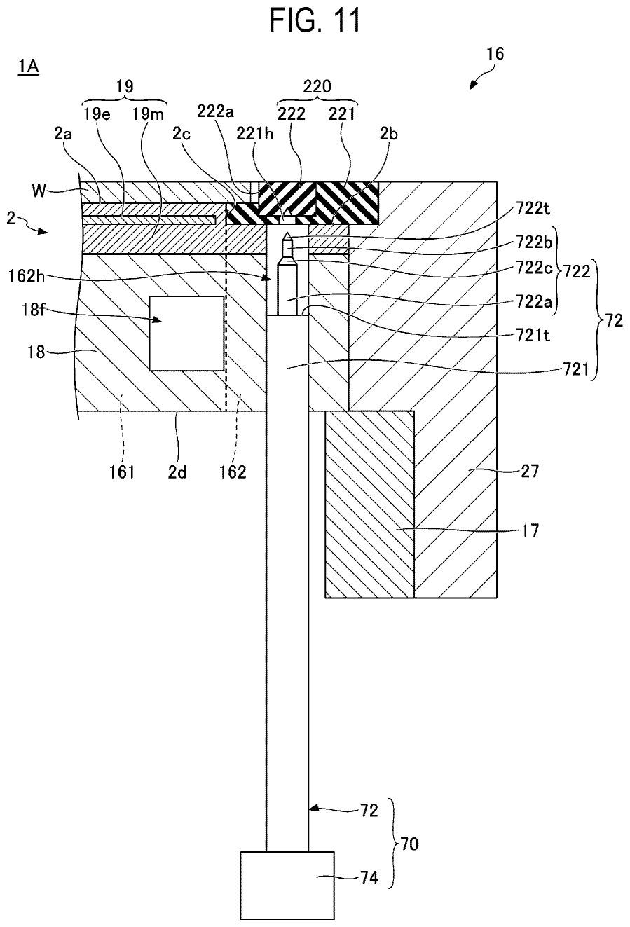

Next, a transfer method when performing state identification and transfer of the edge ring ER by the leakage check illustrated FIG. 5B is described. FIG. 12 is a flowchart illustrating a processing flow in a transfer method according to a third example. Further, in description of the transfer method according to the third example, a case where the ring 113 is transferred between the ring accommodation module RSM and the processing module PM1 is described in detail. Even in a case where a processing module for an exchange target is any one of the processing modules PM2 to PM7, the same method as a case where the processing module for the exchange target is the processing module PM1 may be used.

When performing the steps to the step S3 in the operation sequence in FIG. 6, the controller CU of the substrate processing system PS performs steps S301 to S308 as the transfer method according to the third example. The steps S301 to S308 are performed as the controller CU controls each part of the substrate processing system PS.

The steps S301 and S302 may be the same as the steps S101 and S102. In addition, in order to perform a leakage check after the step S302 (before the step S303), the controller CU performs a processing of electrostatically attracting the edge ring ER to the ring support surface 112b.

In the step S303, in order to acquire an index related to a position misalignment amount of the edge ring ER, the controller CU performs a leakage check by the plasma processing apparatus 1. As illustrated in FIG. 5B, in the leakage check, the controller 90 of the plasma processing apparatus 1 supplies a gas to a gap between the ring support surface 112b to which the edge ring ER is electrostatically attracted and the edge ring ER, and stops the supply of the gas when a pressure in the gap reaches a target pressure. Further, the controller 90 measures a pressure in a flow path after a predetermined time elapses from the stop of the supply by the pressure sensor 67.

The controller CU acquires, as the index related to the position misalignment amount of the edge ring ER, a measurement result of the pressure sensor 67 after the predetermined time elapses, and determines a position misalignment of the edge ring ER (the step S304 in FIG. 12). For example, if the pressure is a pre-stored pressure threshold value or more, the controller CU determines that the edge ring ER is not misaligned (normal). Meanwhile, if the pressure less than the pressure threshold value, the controller CU determines that the edge ring ER is misaligned (abnormal). Further, if the edge ring ER is not misaligned (the step S304: “YES”), the controller CU proceeds to the step S305. If the edge ring ER is misaligned (the step S304: “NO”), the controller CU proceeds to the step S308.

In the step S305, the controller CU ends the leakage check and the misalignment identification and correction processing. Further, in the step S306, the controller CU performs an unloading processing of unloading the edge ring ER from the processing module PM1 by the transfer robot TR1. The step S306 corresponds to the step S5 in FIG. 6. Further, since the leakage check is performed in a state in which the edge ring ER is electrostatically attracted, the controller CU may perform a charge removal processing of the edge ring ER before the step S306 (or the step S308 to be described later). Further, in the step S307, the controller CU performs a loading processing of loading the edge ring ER into the ring accommodation module RSM by the transfer robot TR1. The step S307 corresponds to the step S6 in FIG. 6.

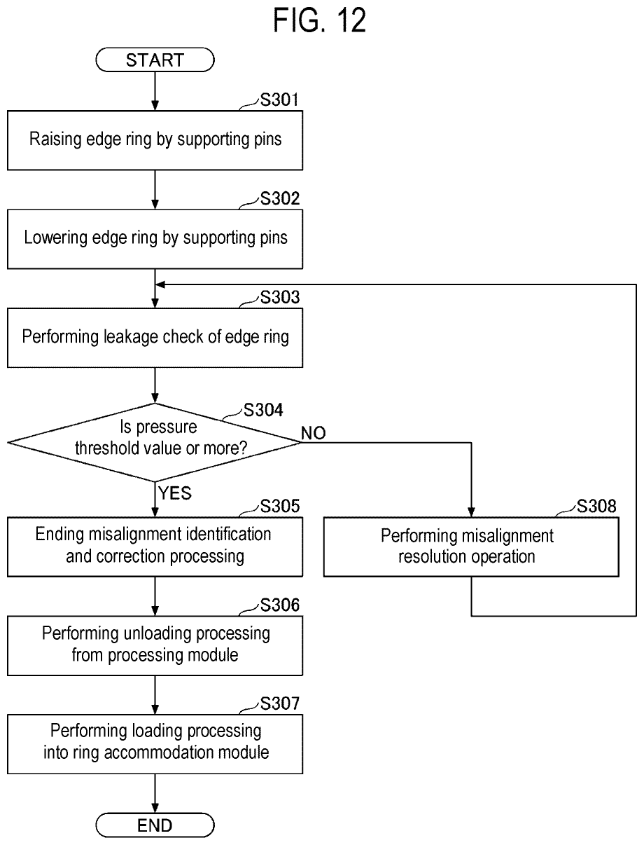

Meanwhile, when a misalignment occurs in the edge ring ER, in the step S308, the controller CU performs a misalignment resolution operation for resolving the misalignment of the edge ring ER. In the misalignment resolution operation, for example, as illustrated in FIGS. 13A to 13C, a recess 114 formed in the edge ring ER and a configuration of each supporting pin 521 may be used.

Specifically, in a lower surface of the edge ring ER, the recess 114 of the edge ring ER is provided as many as the supporting pins 521. As illustrated in FIG. 13A, each recess 114 includes a flat bottom portion 114a and a tapered portion 114b having an inner diameter widened toward an opening portion while surrounding a periphery of the bottom portion 114a. The bottom portion 114a is formed wider than the outer diameter of the upper pin 524 of the supporting pin 521, and have, for example, about 2 mm. The tapered portion 114b is smoothly connected to the bottom portion 114a and the lower surface of the edge ring ER through rounded edge portions.

When a position misalignment occurs on the edge ring ER having the recess 114, for example, the upper end surface 524a of the supporting pin 521 and the tapered portion 114b face each other. In this case, the controller CU performs, as the misalignment resolution operation, an operation of raising the supporting pins 521 by the plasma processing apparatus 1.

That is, as illustrated in FIG. 13B, when raising the supporting pin 521, the upper end surface 524a of the supporting pin 521 comes in contact with the tapered portion 114b of the edge ring ER. Therefore, the tapered portion 114b slides along a slope of the tapered portion 114b with respect to the supporting pin 521. As a result, as illustrated in FIG. 13C, the edge ring ER moves in a horizontal direction to guide the supporting pin 521 to a substantially central portion of the bottom portion 114a. By the movement in the horizontal direction, the misalignment of the edge ring ER is resolved.

Back to FIG. 12, when performing the misalignment resolution operation in the step S308, the controller CU returns to the step S303 to perform the leakage check again. This is for the purpose of identifying whether the misalignment of the edge ring ER has been resolved by the misalignment resolution operation. If the measured pressure is less than the pressure threshold value, the misalignment of the edge ring ER is not resolved, and hence the controller CU repeats the misalignment resolution operation (the step S308). Meanwhile, if the measured pressure is the pressure threshold value or more, the controller CU proceeds to the step S305 to end the misalignment identification and correction processing.

As described above, in the substrate processing system PS and the transfer method, it is possible to identify the misalignment of the edge ring ER by performing the leakage check. Further, in the substrate processing system PS and the transfer method, it is possible to correct the misalignment of the edge ring ER by using the recess 114 of the edge ring ER and the shape of the supporting pin 521. As a result, the transfer robot TR1 may transfer the edge ring ER without interfering with other parts.

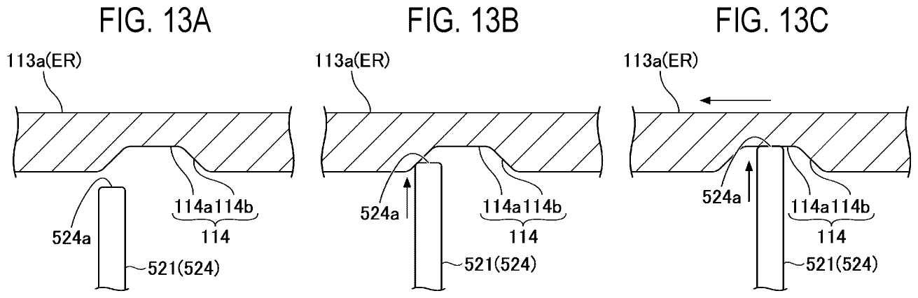

FIG. 14 is a flowchart illustrating a transfer method according to a fourth example. The transfer method according to the fourth example performs state identification and transfer of the edge ring ER by performing a leakage check in the processing module PM1. Further, in description of the transfer method according to the fourth example, a case where the ring 113 is transferred between the ring accommodation module RSM and the processing module PM1 is described in detail. Even in a case where a processing module for an exchange target is any one of the processing modules PM2 to PM7, the same method as a case where the processing module for the exchange target is the processing module PM1 may be used.

When performing the steps to the step S3 in the operation sequence in FIG. 6, the controller CU of the substrate processing system PS performs steps S401 to S410 as the transfer method according to the fourth example. The steps S401 to S410 are performed as the controller CU controls each part of the substrate processing system PS.

The steps S401 to S404 may be the same as the steps S301 to S304. In addition, in order to perform a leakage check after the step S402 (before the step S403), the controller CU performs a processing of electrostatically attracting the edge ring ER to the ring support surface 112b. Further, if the pressure of the pressure sensor 67 is less than the pressure threshold value in the step S404 (the step S404: “NO”), the controller CU proceeds to the step S405. If the pressure of the pressure sensor 67 is the pressure threshold value or more (the step S404: “YES”), the controller CU omits the steps S405 to S408 and proceeds to the step S409.

In the step S405, the controller CU operates the transfer robot TR1 and detects a position (an index related to a position misalignment amount) of the edge ring ER by the position detection sensor S1 or S2. Accordingly, the controller CU may obtain a gap amount (a position misalignment amount) between the substrate support surface 112a and the edge ring ER by receiving a detection result of the position detection sensor S1 or S2.

Further, controller CU may perform correction and movement illustrated in of FIGS. 8D to 8F by utilizing the position misalignment amount. Further, since the leakage check is performed in a state in which the edge ring ER is electrostatically attracted, the controller CU may perform a charge removal processing of the edge ring ER from the determination “YES” in the step S404 and before the step S406. Therefore, in the step S406, the controller CU raises the edge ring ER by the supporting pins 521 in a state in which the attraction of the edge ring ER to the ring support surface 112b is resolved. That is, after the position misalignment amount is detected, it is possible to transfer the edge ring ER to the transfer robot TR1 while the position of the edge ring ER is prevented from being further misaligned. An operation in the step S407 may be the same operation as the step S106 in FIG. 7, and an operation in the step S408 may be the same operation as the step S107 in FIG. 7.

Further, in the step S409, the controller CU performs an unloading processing of unloading the edge ring ER from the processing module PM1 by the transfer robot TR1. The step S409 corresponds to the step S5 in FIG. 6. Further, in the step S410, the controller CU performs a loading processing of loading the edge ring ER into the ring accommodation module RSM by the transfer robot TR1. The step S410 corresponds to the step S6 in FIG. 6.

As described above, when recognizing a misalignment of the edge ring ER in the leakage check, the transfer method according to the fourth example detects a position of the edge ring ER by the position detection sensor S1 or S2 of the transfer robot S1 or S2. Accordingly, the controller CU may certainly detect a position misalignment amount of the edge ring ER, and thus it is possible to correct and move the edge ring ER with a high degree of precision. As a result, the transfer method may transfer the edge ring ER without interfering with other parts.

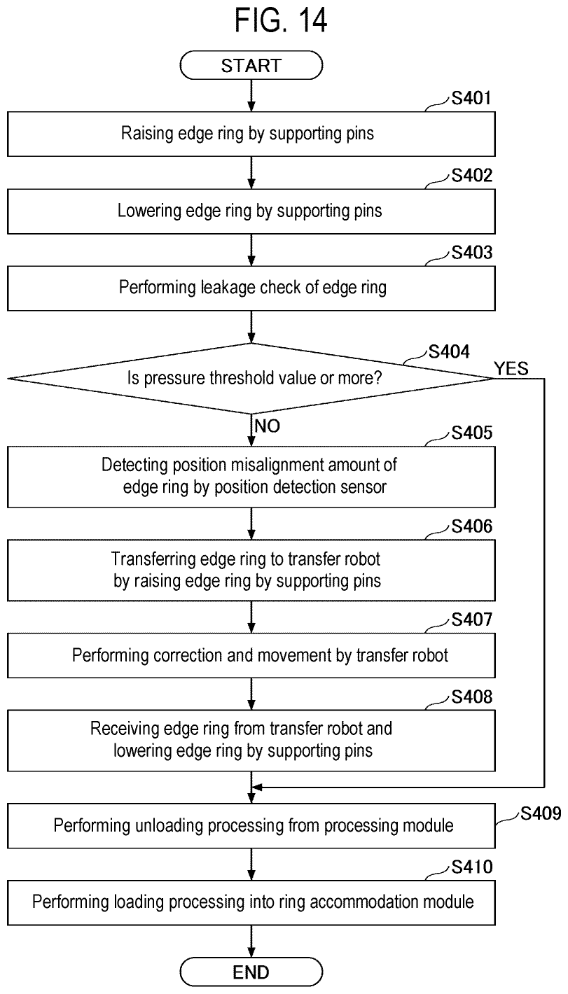

FIG. 15 is a flowchart illustrating a transfer method according to a fifth example. The transfer method according to the fifth example performs state identification and transfer of the edge ring ER by performing a leakage check in the processing module PM1. Further, in description of the transfer method according to the fifth example, a case where the ring 113 is transferred between the ring accommodation module RSM and the processing module PM1 is described in detail. Even in a case where a processing module for an exchange target is any one of the processing modules PM2 to PM7, the same method as a case where the processing module for the exchange target is the processing module PM1 may be used.

When performing the steps to the step S3 in the operation sequence in FIG. 6, the controller CU of the substrate processing system PS performs steps S501 to S511 as the transfer method according to the fifth example. The steps S501 to S511 are performed as the controller CU controls each part of the substrate processing system PS.

The steps S501 to S504 may be the same as the steps S301 to S304. In addition, in order to perform a leakage check after the step S502 (before the step S503), the controller CU performs a processing of electrostatically attracting the edge ring ER to the ring support surface 112b. Further, if the pressure of the pressure sensor 67 is less than the pressure threshold value in the step S504 (the step S504: “NO”), the controller CU proceeds to the step S505. If the pressure of the pressure sensor 67 is the pressure threshold value or more, the controller CU proceeds to the step S509 (the step S504: “YES”).

The steps S505 and S506 may be the same as the steps S205 and S206 in the transfer method according to the second example. Further, since the leakage check is performed in a state in which the edge ring ER is electrostatically attracted, the controller CU may perform a charge removal processing of the edge ring ER before the step S505 (or before the step S509 to be described later).

In the step S507, the controller CU detects a position misalignment amount of the edge ring ER by the position detection sensors S11 and S12 installed in the vicinity of the gate valve (not illustrated) which partitions the vacuum transfer module TM and the processing module PM1. For example, when transferring the edge ring ER by the transfer robot TR1, the controller CU performs detection by the position detection sensors S11 and S12 and calculates a position of the edge ring ER based on a position at which the position detection sensors S11 and S12 are shaded by the edge ring ER and a time for which the position detection sensors S11 and S12 are shaded by the edge ring ER. Further, based on the position of the edge ring ER and a preset reference position, the controller CU calculates a position misalignment amount (an index related to the position misalignment amount) of the edge ring ER from the reference position.

After calculating the position misalignment amount when unloading the edge ring ER, the controller CU performs a loading processing of loading the edge ring ER into the ring accommodation module RSM by the transfer robot TR1 (the step S508). In the loading processing, when loading the edge ring ER into the accommodation module (e.g., the cassette which is not illustrated) of the ring accommodation module RSM, the controller CU sets a movement amount of the transfer robot TR1 based on the position misalignment amount acquired in the step S507, and corrects and moves the transfer robot TR1. Accordingly, the edge ring ER is returned to the normal position by the transfer robot TR1 without interfering with the ring accommodation module RSM. Thus, the controller CU may smoothly accommodate the edge ring ER without interfering with other parts.

Meanwhile, if a leakage amount is less than a threshold value, the edge ring ER may not be misaligned (or the position misalignment amount may be sufficiently small), and hence the controller CU performs ordinary transfer (of not performing movement and correction) in the steps S509 to S511. The steps S509 to S511 may be the same as the steps S208 to S210.

As described above, when recognizing a misalignment of the edge ring ER in the leakage check, the transfer method according to the fifth example detects the position of the edge ring ER by the position detection sensors S11 and S12 of the vacuum transfer module TM. In this case, the controller CU may certainly detect a position misalignment amount of the edge ring ER, and thus it is possible to correct and move the edge ring ER with a high degree of precision when loading the edge ring ER into the ring accommodation module RSM.

In addition, when detecting a position of the edge ring ER by the position detection sensor S11 and S12 of the vacuum transfer module TM, movement and correction may be performed in the processing module PM1 by returning the edge ring ER to the processing module PM1 for the time being without transferring the edge ring ER to the ring accommodation module RSM after the detection.

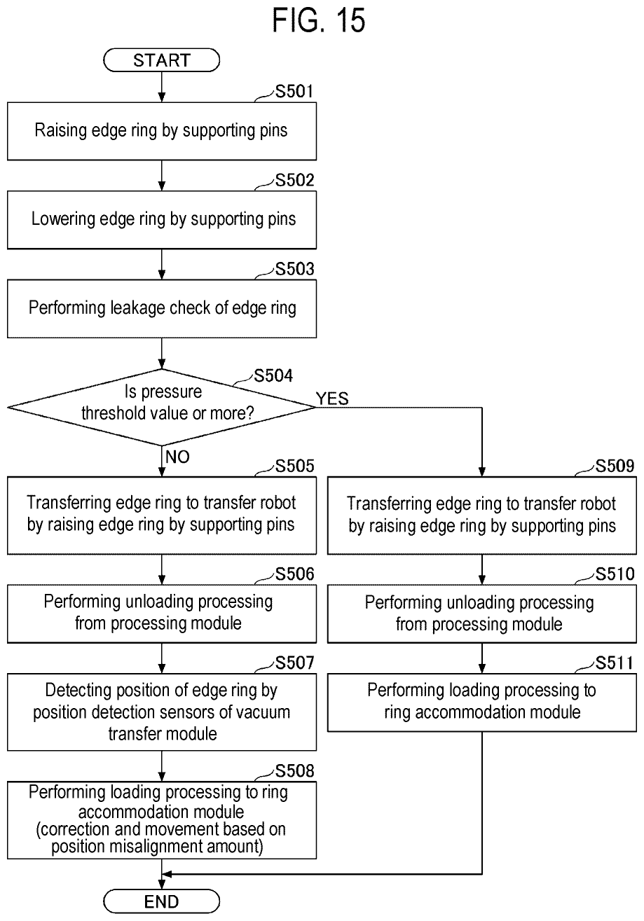

Next, a transfer method when performing state identification and transfer of the edge ring ER by the camera CM of the transfer robot TR1 illustrated in FIG. 5C, is described. FIG. 16 is a flowchart illustrating a processing flow in a transfer method according to a sixth example. Further, in description of the transfer method according to the sixth example, a case where the ring 113 is transferred between the ring accommodation module RSM and the processing module PM1 is described in detail. Even in a case where a processing module for an exchange target is any one of the processing modules PM2 to PM7, the same method as a case where the processing module for the exchange target is the processing module PM1 may be used.

When performing the steps to the step S3 in the operation sequence in FIG. 6, the controller CU of the substrate processing system PS performs steps S601 to S609 as the transfer method according to the sixth example. The steps S601 to S609 are performed as the controller CU controls each part of the substrate processing system PS.

The steps S601 and S602 may be the same as the steps S101 and S102 in the transfer method according to the first example.

In the step S603, the controller CU acquires image information as an index related to a position misalignment amount by operating the transfer robot TR1 and imaging the substrate support surface 112a and the edge ring ER by the camera CM. The controller CU performs an image processing on the image information to extract a gap amount (a position misalignment amount) between the substrate support surface 112a and the edge ring ER from color or contrast information.

Therefore, based on the position misalignment amount extracted from the image information and a pre-stored threshold value, the controller CU determines whether the position misalignment amount of the edge ring ER is the threshold value or more (the step S604). If the position misalignment amount is less than the threshold value (the step S604: “NO”), the edge ring ER may not be misaligned (or the position misalignment amount may be sufficiently small). Therefore, the controller CU skips the steps S605 to S607 and immediately proceeds to the step S608. Meanwhile, if the position misalignment amount is the threshold value or more (the step S604: “YES”), the edge ring ER may be misaligned (or the position misalignment amount may be large). In this case, the controller CU detects an error of the edge ring ER, and proceeds to step S605.

In addition, the steps S605 to step S607 may be the same as the steps S105 to S107 in the transfer method according to the first example.

Further, in the step S608, the controller CU performs an unloading processing of unloading the edge ring ER from the processing module PM1 by the transfer robot TR1. The step S608 corresponds to the step S5 in FIG. 6. Further, in the step S609, the controller CU performs a loading processing of loading the edge ring ER into the ring accommodation module RSM by the transfer robot TR1. The step S609 corresponds to the step S6 in FIG. 6.

As described above, in the transfer method according to the sixth example, it is possible to obtain the position misalignment amount of the edge ring ER by imaging the edge ring ER by the camera of the transfer robot TR1. Thus, the controller CU operates the transfer robot TR1, based on the position misalignment amount of the image information, so that it is possible to transfer the edge ring ER without interfering with other parts.

In addition, a transfer method in a configuration in which the camera CM is applied to the transfer robot TR1 is not limited to the transfer method according to the sixth example, and may be used, for example, in combination with the leakage check or in combination with the position detection sensor S11 and S12 of the transfer module TM. As for the position misalignment amount of the edge ring ER, image information of the camera CM (or a detection result of the position detection sensor S1 or S2) and a detection result of the position detection sensors S11 and S12 are used, so that it is possible to further increase precision of detection or precision of correction and movement. In addition, in the transfer method according to the sixth example, when acquiring an index related to a position misalignment amount of the edge ring ER by the position detection sensor S1 or S2 of the transfer robot TR1, detection may be performed in a state in which the edge ring ER is supported by the supporting pins 521. That is, in the step S601, the controller CU may stop the supporting pins 521 at a position at which the edge ring ER is separated from the ring support surface 112b and acquire the position misalignment amount by the position detection sensor S1 or S2, or the controller CU may acquire the position misalignment amount by the position detection sensor S1 or S2 at an arbitrary pin height which is higher than the position at which the edge ring ER is separated from the ring support surface 112b and at which the upper surface of the edge ring ER is below the position detection sensors S1 and S2 (see FIG. 9).

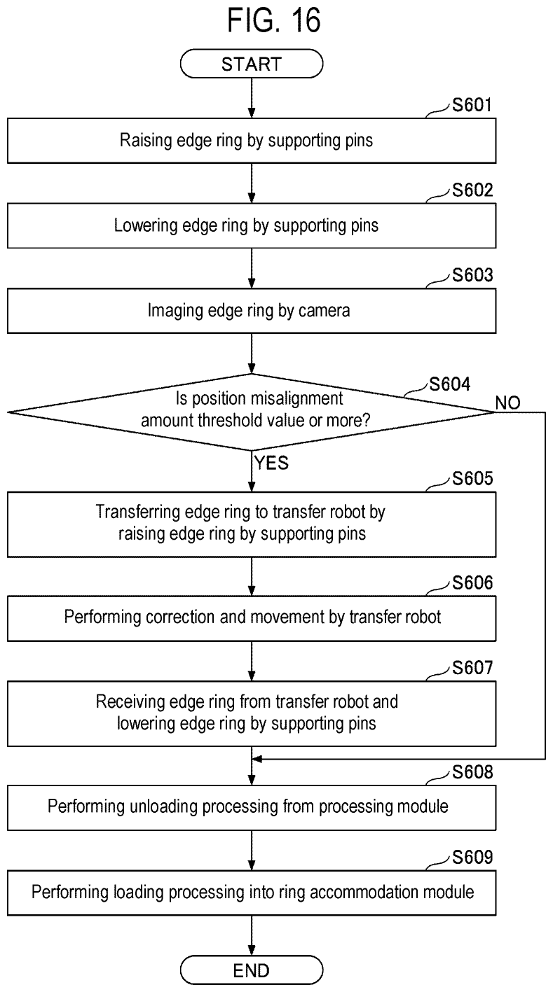

In addition, in the configuration in which the camera CM is applied to the transfer robot TR1, as illustrated in FIG. 17, an imaging direction of the camera CM is appropriately adjusted, so that it is possible not only to image the substrate support surface 112a or the edge ring ER below the camera CM but also to image a front in a transfer direction. Therefore, it is possible to image the edge ring ER being supported by the supporting pins 521 and obliquely inclined while getting out of some supporting pins 521 using the camera CM. Further, it is possible to image the edge ring ER is supported on the electrostatic chuck 112 while getting out of all the supporting pins 521 using the camera CM.

The controller CU image-processes and analyzes such image information to recognize that the edge ring ER is inclined or that the edge ring ER gets out of all the supporting pins. For example, the camera CM images a plurality of image information in movement of the transfer robot TR1, and the controller CU performs calculation by matching positions of the edge ring ER and the transfer robot TR1 in the plurality of image information. Accordingly, the controller CU may calculate a three-dimensional form (posture and position) of the edge ring ER with a high degree of precision. Further, the controller CU may accumulate image information acquired for each image of the edge ring ER and learn recognition of the edge ring ER from images of the edge ring ER, which are included the plurality of accumulated image information. Accordingly, when acquiring image information next time, it is possible to increase extraction precision of the edge ring ER from the image information. When recognizing that the edge ring ER is inclined or that the edge ring ER gets out of all the supporting pins, the controller CU may be configured to issue an alarm.

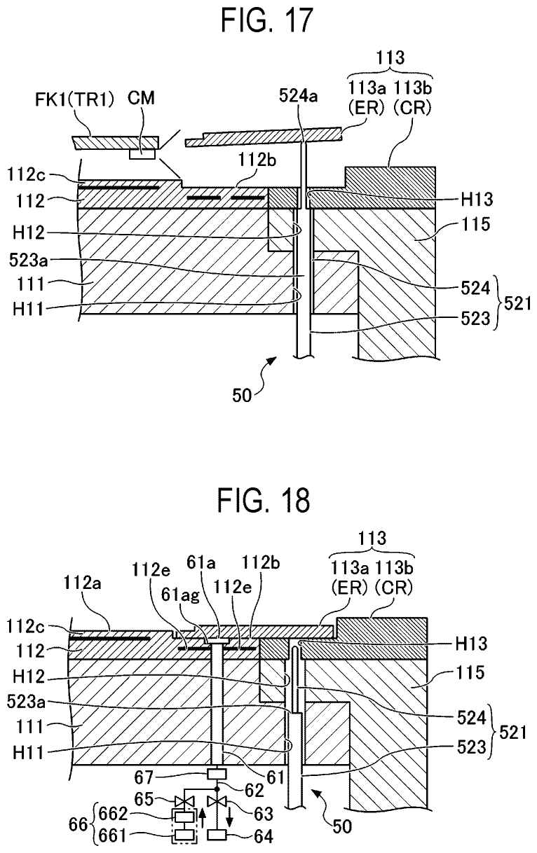

FIG. 18 is a view illustrating a modification of FIG. 5B, which is a configuration of performing a leakage check of gas as an index related to a position misalignment amount of the edge ring. As illustrated in FIG. 18, the configuration of performing the leakage check may be a configuration including a groove 61ag that communicates with the gas supply port 61a while being recessed downward in the ring support surface 112b of the peripheral edge of the electrostatic chuck 112. The groove 61ag is formed in an annular shape that goes around in a circumferential direction of the ring support surface 112b. According to the configuration described above, the groove 61ag may supply a gas such as He gas to the entire rear surface of the inner ring 113a in the circumferential direction to perform a leakage check of the gas.

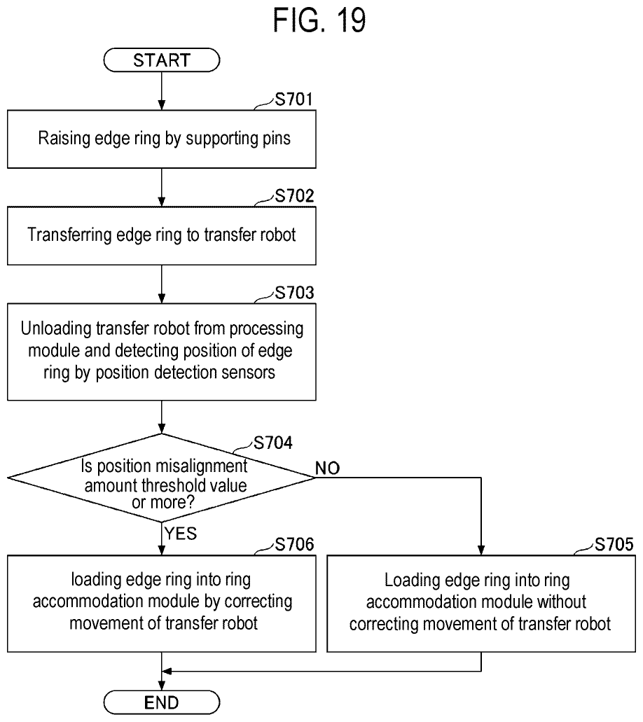

FIG. 19 is a flowchart illustrating an operation sequence of transfer of the edge ring ER according to a modification. In the modification shown in FIG. 19, the substrate processing system PS and the transfer method may detect a misalignment amount of the edge ring ER by the position detection sensors S11 and S12 of the vacuum transfer module TM when unloading the edge ring ER from the processing module PM1. Further, the substrate processing system PS loads the edge ring ER into the ring accommodation module RSM while correcting a position of the edge ring ER based on the misalignment amount of the edge ring ER, which is detected by the position detection sensors S11 and S12. In addition, even in a case where a processing module for an exchange target is any one of the processing modules PM2 to PM7, the same method as a case where the processing module for the exchange target is the processing module PM1 may be used. In this case, a position detection sensor located at a position adjacent to each processing module may be used.

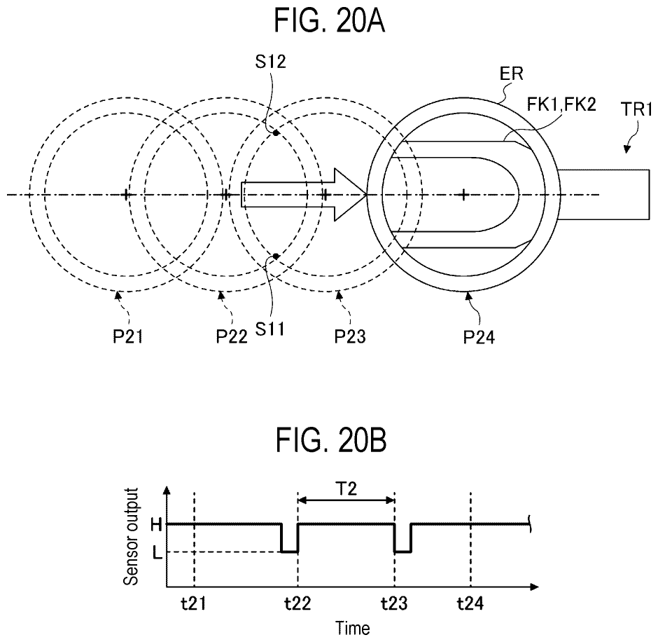

The detection of the misalignment amount of the edge ring ER by the position detection sensors S11 and S12 may be executed by a method shown in FIGS. 20A and 20B. FIG. 20A is a view illustrating a relationship between a position of the edge ring ER and positions of the position detection sensors S11 and S12. FIG. 20B is a view illustrating a change in sensor output of the position detection sensors S11 and S12 when transferring the edge ring ER from a position P21 to a position P24. Further, in FIG. 20B, a time at the position P21 represents t21, a time at the position P22 represents t22, a time at the position P23 represents t23, and a time at the position P24 represents t24. Based on a position of the edge ring ER, which is detected by the position detection sensors S11 and S12, and a preset reference position, the controller CU calculates a misalignment amount of the edge ring ER from the reference position. Then, the controller CU loads the edge ring ER into the ring accommodation module RSM by the transfer robot TR1 to correct the calculated misalignment amount. Accordingly, even if a position of the edge ring ER held by the upper fork FK1 or the lower fork FK2 is misaligned from the reference position, it is possible to load the edge ring ER at a predetermined position of the ring accommodation module RSM.

The position of the edge ring ER held by the upper fork FK1 or the lower fork FK2 may be calculated based on an output change of the position detection sensors S11 and S12, which is generated as an inner peripheral edge passes through the position detection sensors S11 and S12. For example, as illustrated in FIG. 20A, when transferring the edge ring ER from the position P24 to the position P24, the position of the edge ring ER may be calculated based on a time T2 for which the edge ring ER moves from the position P22 to the position P23. The position P22 is a position at which the sensor output of the position detection sensor S11 and S12 is changed from a low (L) level to a high (H) level, and the position P23 is a position at which the sensor output of the position detection sensors S11 and S12 is changed from the high (H) level to the low (L) level. Specifically, as illustrated in FIG. 20B, the position of the edge ring ER may be calculated by T2=t23−t22 using the time t22 at the position P22 and the time t23 at the position P23. Further, in FIGS. 20A and 20B, a case where a position at which the position detection sensor S11 is shaded by the edge ring ER and a position at which the position detection sensor S2 is shaded by the edge ring ER are the same is shown, but the positions may be different from each other.

The controller CU controls steps S701 to S706 in FIG. 19. First, the controller CU raises the supporting pins 521 of the plasma processing apparatus 1, and allows the edge ring ER to be spaced apart from the ring support surface 112b of the substrate support 11 (the step S701 in FIG. 19). When residual attraction exists between the ring support surface 112b and the edge ring ER, a misalignment may occur in the edge ring ER when raised.

Subsequently, the controller CU enters the transfer robot TR1 below the edge ring ER in the plasma processing space 10s, and transfers the edge ring ER to the transfer robot TR1 by lowering the supporting pin 521 (the step S702 in FIG. 19).

After that, the controller CU unloads the transfer robot TR1 from the processing module PM1, and detects a position of the edge ring ER held by the transfer robot TR1 by the position detection sensors S11 and S12 (the step S703). The transfer robot TR1 moves to pass through a middle of the position detection sensors S11 and S12, and the center of the edge ring ER passes the middle when the edge ring ER is not misaligned. Meanwhile, when the edge ring ER is misaligned, a misalignment of the edge ring ER (a position misalignment amount and a position misalignment direction of the center of the edge ring ER with respect to a reference position of the transfer robot TR) may be calculated by the position detection sensors S11 and S12.

Subsequently, the controller CU compares the position misalignment amount of the edge ring ER with a pre-stored threshold value, and determines whether the position misalignment amount of the edge ring ER is the threshold value or more (the step S704). If the position misalignment amount is less than the threshold value (the step S704: “NO”), the edge ring ER may not be misaligned (or the position misalignment amount may be sufficiently small). In this case, the controller CU proceeds to the step S705.

In the step S705, the controller CU loads the edge ring ER into the ring accommodation module RSM by transferring the edge ring ER without correcting movement of the transfer robot TR1. Accordingly, the substrate processing system PS may smoothly load the edge ring ER into the ring accommodation module RSM.

Meanwhile, if the position misalignment amount is the threshold value or more (the step S704: “YES”), the edge ring ER may be misaligned (or the position misalignment amount may be large). In this case, the controller CU proceeds to the step S706 in FIG. 19 to load the edge ring ER into the ring accommodation module RSM while correcting the movement of the transfer robot TR1 based on the misalignment of the edge ring ER, which is calculated from a detection result of the position detection sensors S11 and S12. At this time, the controller CU sets a movement amount and a movement direction in the correction and movement of the transfer robot TR1 based on the acquired misalignment amount and the acquired misalignment direction, and corrects the movement of the transfer robot TR1. Accordingly, even if a misalignment occurs in the edge ring ER, the substrate processing system PS may smoothly load the edge ring ER into the ring accommodation module RSM.

In addition, the transfer method in FIG. 19 may be applied to even a case where the cover ring CR is unloaded from any one of the processing modules PM1 to PM7 to the vacuum transfer module TM and transferred into the ring accommodation module RSM. Further, the transfer method in FIG. 19 may be applied to even a case where the upper ring 222 or the lower ring 221 in FIG. 11 is unloaded from any one of the processing modules PM1 to PM7 to the vacuum transfer module TM and transferred to the load lock module LLM. Further, the transfer method in FIG. 19 may be applied to even a case where the upper ring 222 or the lower ring 221 in FIG. 11 is unloaded from any one of the processing modules PM1 to PM7 to the vacuum transfer module TM and transferred to the ring accommodation module RSM.

Alternatively, as another modification, the substrate processing system PS and the transfer method may detect a position of the edge ring by the position detection sensor S1 or S2, by raising the edge ring ER and then lowering the edge ring ER by the supporting pins 521, to place the edge ring ER on the ring support surface 112b. If a position misalignment amount of the edge ring ER is smaller than a threshold value, the substrate processing system PS and the transfer method may perform an unloading processing from the processing module PM1 (unloading while detecting a position of the edge ring ER by the position detection sensors S11 and S12, or the like) by raising the edge ring ER again by the supporting pins 521 and transferring the edge ring ER to the transfer robot TR1, and perform a loading processing into the ring accommodation module RSM (correction and movement based on the position misalignment amount). In the unloading processing of the edge ring ER from the processing module PM1 and the loading processing of the edge ring ER into the ring accommodation module RSM, the processing flow shown in FIG. 19 may be performed. Meanwhile, when the position misalignment amount of the edge ring ER is the threshold value or more, the substrate processing system PS and the transfer method may perform a processing of taking out the edge ring ER by issuing an alarm and opening the plasma processing chamber 10 in an atmosphere.

The embodiment disclosed in the above includes, for example, the following aspect.

### (Supplementary Note 1)

A substrate processing system including:
a processing module including a processing chamber, a substrate support configured to support a substrate and a ring disposed at a periphery of the substrate in the processing chamber, and a lifter configured to raise and lower the ring;
a vacuum transfer module connected to the processing module and including a transfer robot configured to transfer the ring; and
a controller,
wherein the controller performs:
   (A) raising the lifter to allow the ring to be spaced apart from a support surface of the substrate support;
   (B) after step (A), acquiring an index related to a position misalignment amount of the ring; and
   (C) determining whether to correct a position of the ring based on the index related to the position misalignment amount, which is acquired in step (B).

### (Supplementary Note 2)

The substrate processing system of Supplementary Note 1, wherein, in step (B), the controller acquires, as the index related to the position misalignment amount, the position of the ring, which is detected by a position detection sensor included in the transfer robot.

### (Supplementary Note 3)

The substrate processing system of Supplementary Note 2, wherein, in step (B), the controller acquires a gap amount of the ring in a horizontal direction with respect to a substrate support surface of the substrate support based on a position of the substrate support surface and the position of the ring, which are detected by the position detection sensor.

### (Supplementary Note 4)

The substrate processing system of any one of Supplementary Notes 1 to 3, wherein, in step (B), the controller acquires, as the index related to the position misalignment amount, a leakage amount of a gas by supplying the gas between the support surface of the substrate support and a rear surface of the ring in a state in which the ring is electrostatically attracted to the support surface.

### (Supplementary Note 5)

The substrate processing system of any one of Supplementary Notes 1 to 4, wherein, in step (B), the controller acquires, as the index related to the position misalignment amount, image information of the ring, which is imaged by a camera included in the transfer robot.

### (Supplementary Note 6)

The substrate processing system of any one of Supplementary Notes 1 to 5, in step (B), the controller acquires, as the index related to the position misalignment amount, the position of the ring, which is detected by a position detection sensor installed in the vacuum transfer module, when unloading the ring from the processing module by the transfer robot.

### (Supplementary Note 7)

The substrate processing system of any one of Supplementary Notes 1 to 6, wherein, if it is determined to perform the correction in step (C), the controller further performs correction and movement of moving the ring according to the position misalignment amount by the transfer robot, and
wherein, if it is determined not to perform the correction in step (C), the controller further performs: transferring the ring by the transfer robot, without performing the correction and movement.

### (Supplementary Note 8)

The substrate processing system of Supplementary Note 7, wherein, if it is determined to perform the correction in step (C), the controller performs the correction and movement by the transfer robot in the processing module.

### (Supplementary Note 9)

The substrate processing system of Supplementary Note 8, wherein, in the correction and movement, the controller sequentially performs:
receiving the ring in which a misalignment occurs from the lifter by the transfer robot;
moving the transfer robot according to the position misalignment amount; and
transferring the ring from the transfer robot to the lifter.

### (Supplementary Note 10)

The substrate processing system of Supplementary Note 8, wherein, in the correction and movement, the controller performs: moving the transfer robot according to the position misalignment amount before receiving the ring from the lifter by the transfer robot.

### (Supplementary Note 11)

The substrate processing system of Supplementary Note 7, wherein, if it is determined to perform the correction in step (C), the controller further performs: transferring the ring to a ring accommodation module configured to accommodate the ring while performing the correction and movement on the ring in which a misalignment occurs by the transfer robot.

### (Supplementary Note 12)

The substrate processing system of any one of Supplementary Notes 1 to 3 and 5, wherein, in step (B), the controller acquires the index related to the position misalignment amount in a state in which the ring is placed on the substrate support by lowering the lifter.

### (Supplementary Note 13)

The substrate processing system of any one of Supplementary Notes 1 to 3 and 5, wherein, in step (B), the controller acquires the index related to the position misalignment amount in a state in which the ring is raised by the lifter in step (A).

### (Supplementary Note 14)

The substrate processing system of any one of Supplementary Notes 1 to 13, further including: a first ring accommodation module connected to the vacuum transfer module and configured to accommodate the ring,
wherein the controller further performs: loading the ring unloaded from the processing module into the first ring accommodation module by the transfer robot.

### (Supplementary Note 15)

The substrate processing system of any one of Supplementary Notes 1 to 13, further including:
an atmospheric transfer module connected to the vacuum transfer module via a load lock module; and
a second ring accommodation module connected to the atmospheric transfer module and configured to accommodate the ring,
wherein the controller further performs: loading the ring unloaded from the processing module into the second ring accommodation module via the load lock module and the atmospheric transfer module by the transfer robot.

### (Supplementary Note 16)

The substrate processing system of any one of Supplementary Notes 1 to 15, wherein the processing module performs a substrate processing in a state in which the ring is electrostatically attracted, and
wherein, before step (A), the controller further performs: removing charges from the ring.

### (Supplementary Note 17)

The substrate processing system of any one of Supplementary Notes 1 to 16, wherein the controller further performs: cleaning of an interior of the processing chamber by generating plasma during step (A) or before and after step (A).

### (Supplementary Note 18)

The substrate processing system of Supplementary Note 17, wherein the cleaning of the interior of the processing chamber during step (A) or after step (A) is performed in a state in which the ring is spaced apart from the support surface of the substrate support.

### (Supplementary Note 19)

The substrate processing system of any one of Supplementary Notes 1 to 18, wherein the lifter includes a supporting pin and an actuator configured to vertically move the supporting pin.

### (Supplementary Note 20)

A transfer method of unloading a ring disposed at a periphery of a substrate from a processing module by a transfer robot of a vacuum transfer module connected to the processing module, wherein the processing module includes a processing chamber, a substrate support configured to support the substrate and the ring in the processing chamber, and a lifter configured to raise and lower the ring, the transfer method including:
(A) raising the lifter to allow the ring to be spaced apart from a support surface of the substrate support;
(B) after step (A), acquiring an index related to a position misalignment amount of the ring; and
(C) determining whether to correct a position of the ring based on the index related to the position misalignment amount, which is acquired in step (B).

In addition, the present disclosure is not limited to the configurations shown herein, including configurations exemplified in the embodiments, combinations with other elements, and the like. In this regard, this may be changed without departing from the spirit of the present disclosure, and may be properly set according to an application form thereof. Further, in items described in a plurality of embodiments, other configurations may be used within a non-contradictory range and may be combined within a non-contradictory range.

For example, in the embodiment, a capacitively coupled plasma apparatus is described as an example. However, the present disclosure is not limited thereto, and may be applied to other plasma apparatuses. For example, instead of the capacitively coupled plasma apparatus, an inductively coupled plasma (ICP) apparatus may be used. In this case, the inductively coupled plasma apparatus includes an antenna and a lower electrode. The lower electrode is disposed in a substrate support, and the antenna is disposed on or above a chamber. Further, an RF generator is coupled to the antenna, and a DC generator is coupled to the lower electrode. Therefore, the RF generator is coupled to an upper electrode of the capacitively coupled plasma apparatus or the antenna of the inductively coupled plasma apparatus. That is, the RF generator is coupled to the plasma processing chamber 10.

This application is based upon and claims the benefit of priority from Japanese Patent Application No. 2022-174836, filed on Oct. 31, 2022, the entire contents of which are incorporated herein by reference.

According to the present disclosure in some embodiments, it is possible to suppress interference between a ring and other parts when transferring the ring.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing system comprising:
a processing module including a processing chamber, a substrate support configured to support a substrate and a ring disposed at a periphery of the substrate in the processing chamber, and a lifter configured to raise and lower the ring;
a vacuum transfer module connected to the processing module and including a transfer robot configured to transfer the ring; and
a controller,
wherein the controller performs:
(A) raising the lifter to allow the ring to be spaced apart from a support surface of the substrate support;
(B) after step (A), acquiring an index related to a position misalignment amount of the ring; and
(C) determining whether to correct a position of the ring based on the index related to the position misalignment amount, which is acquired in step (B).

2. The substrate processing system of claim 1, wherein, in step (B), the controller acquires, as the index related to the position misalignment amount, the position of the ring, which is detected by a position detection sensor included in the transfer robot.

3. The substrate processing system of claim 2, wherein, in step (B), the controller acquires a gap amount of the ring in a horizontal direction with respect to a substrate support surface of the substrate support based on a position of the substrate support surface and the position of the ring, which are detected by the position detection sensor.

4. The substrate processing system of claim 1, wherein, in step (B), the controller acquires, as the index related to the position misalignment amount, a leakage amount of a gas by supplying the gas between the support surface of the substrate support and a rear surface of the ring in a state in which the ring is electrostatically attracted to the support surface.

5. The substrate processing system of claim 1, wherein, in step (B), the controller acquires, as the index related to the position misalignment amount, image information of the ring, which is imaged by a camera included in the transfer robot.

6. The substrate processing system of claim 1, wherein, in step (B), the controller acquires, as the index related to the position misalignment amount, the position of the ring, which is detected by a position detection sensor installed in the vacuum transfer module, when unloading the ring from the processing module by the transfer robot.

7. The substrate processing system of claim 1, wherein, if it is determined to perform the correction in step (C), the controller further performs correction and movement of moving the ring according to the position misalignment amount by the transfer robot, and
wherein, if it is determined not to perform the correction in step (C), the controller further performs: transferring the ring by the transfer robot, without performing the correction and movement.

8. The substrate processing system of claim 7, wherein, if it is determined to perform the correction in step (C), the controller performs the correction and movement by the transfer robot in the processing module.

9. The substrate processing system of claim 8, wherein, in the correction and movement, the controller sequentially performs:
receiving the ring in which a misalignment occurs from the lifter by the transfer robot;
moving the transfer robot according to the position misalignment amount; and
transferring the ring from the transfer robot to the lifter.

10. The substrate processing system of claim 8, wherein, in the correction and movement, the controller performs: moving the transfer robot according to the position misalignment amount before receiving the ring from the lifter by the transfer robot.

11. The substrate processing system of claim 7, wherein, if it is determined to perform the correction in step (C), the controller further performs: transferring the ring to a ring accommodation module configured to accommodate the ring while performing the correction and movement on the ring in which a misalignment occurs by the transfer robot.

12. The substrate processing system of claim 1, wherein, in step (B), the controller acquires the index related to the position misalignment amount in a state in which the ring is placed on the substrate support by lowering the lifter.

13. The substrate processing system of claim 1, wherein, in step (B), the controller acquires the index related to the position misalignment amount in a state in which the ring is raised by the lifter in step (A).

14. The substrate processing system of claim 1, further comprising: a first ring accommodation module connected to the vacuum transfer module and configured to accommodate the ring,
wherein the controller further performs: loading the ring unloaded from the processing module into the first ring accommodation module by the transfer robot.

15. The substrate processing system of claim 1, further comprising:
an atmospheric transfer module connected to the vacuum transfer module via a load lock module; and
a second ring accommodation module connected to the atmospheric transfer module and configured to accommodate the ring,
wherein the controller further performs: loading the ring unloaded from the processing module into the second ring accommodation module via the load lock module and the atmospheric transfer module by the transfer robot.

16. The substrate processing system of claim 1, wherein the processing module performs a substrate processing in a state in which the ring is electrostatically attracted, and
wherein, before step (A), the controller further performs: removing charges from the ring.

17. The substrate processing system of claim 1, wherein the controller further performs: cleaning of an interior of the processing chamber by generating plasma during step (A) or before and after step (A).

18. The substrate processing system of claim 17, wherein the cleaning of the interior of the processing chamber during step (A) or after step (A) is performed in a state in which the ring is spaced apart from the support surface of the substrate support.

19. The substrate processing system of claim 1, wherein the lifter includes a supporting pin and an actuator configured to vertically move the supporting pin.

20. A transfer method of unloading a ring disposed at a periphery of a substrate from a processing module by a transfer robot of a vacuum transfer module connected to the processing module, wherein the processing module includes a processing chamber, a substrate support configured to support the substrate and the ring in the processing chamber, and a lifter configured to raise and lower the ring, the transfer method comprising:
(A) raising the lifter to allow the ring to be spaced apart from a support surface of the substrate support;
(B) after step (A), acquiring an index related to a position misalignment amount of the ring; and
(C) determining whether to correct a position of the ring based on the index related to the position misalignment amount, which is acquired in step (B).
